(19) United States
(12) Patent Application Publication
(10) Pub. No.: US 2013/0032767 A1
(43) Pub. Date: Feb. 7, 2013

(54) OCTAPOD SHAPED NANOCRYSTALS AND USE THEREOF

(71) Applicants: Liberato Manna, Genova (IT); Dirk Dorfs, Campomorone (IT); Karol Miszta, Stoczek Lukowski (PL); Sasanka Deka, Delhi (IN); Alessandro Genovese, Torino (IT); Giovanni Bertoni, Modena (IT); Rosaria Brescia, Bari (IT); Sergio Marras, Cagliari (IT); Yang Zhang, Genova (IT); Roman Krahne, Genova (IT); Roberto Cingolani, Arnesano (IT)

(72) Inventors: Liberato Manna, Genova (IT); Dirk Dorfs, Campomorone (IT); Karol Miszta, Stoczek Lukowski (PL); Sasanka Deka, Delhi (IN); Alessandro Genovese, Torino (IT); Giovanni Bertoni, Modena (IT); Rosaria Brescia, Bari (IT); Sergio Marras, Cagliari (IT); Yang Zhang, Genova (IT); Roman Krahne, Genova (IT); Roberto Cingolani, Arnesano (IT)

(73) Assignee: FONDAZIONE ISTITUTO ITALIANO DI TECNOLOGIA, Genova (IT)

(21) Appl. No.: 13/196,123

(22) Filed: Aug. 2, 2011

(51) Int. Cl. H01B 1/10; H01L 21/20; B82Y 40/00

(52) U.S. Cl. 252/519.4; 438/488; 257/E21.09; 977/813

(57) ABSTRACT

This invention relates to the controlled growth of uniform octapod-shaped colloidal nanocrystals and use thereof. These octapod-shaped nanocrystals can be applied in many fields of technology. This represents the first approach reported so far for the predictable and controlled fabrication of octapod-shaped nanocrystals. The synthesis approach is applicable to a broad range of materials, such as group II-VI semiconductor nanocrystals but is not limited to these materials. Using several cation exchange and oxidation procedures, we also demonstrate in this application that extremely uniform octapod-shaped nanocrystals of other materials can be synthesized, including various semiconductors, metals and insulators.

This invention relates to the controlled growth of uniform octapod-shaped colloidal nanocrystals and use thereof. These octapod-shaped nanocrystals can be applied in many fields of technology.

This specification represents the first approach reported so far for the predictable and controlled fabrication of octapod-shaped nanocrystals. The synthesis approach is applicable to a broad range of materials, such as group II-VI semiconductor nanocrystals but is not limited to these materials. Using several cation exchange and oxidation procedures, we also demonstrate in this application that extremely uniform octapod-shaped nanocrystals of other materials can be synthesized, including various semiconductors, metals and insulators.

### STATE OF THE PRIOR ART

There are numerous reports in the literature describing the synthesis of rod-shaped and of branched nanocrystals like nano-tetrapods (i.e. branched nanocrystals consisting of four rod sections departing at tetrahedral angle from a common central region) [1-6], or of nanocrystals with a hyper-branched shape (i.e. tree-like or urchin-like) [7]. The detailed synthesis procedures of colloidal nanocrystals have been described in many patents and articles [1-7]. Broadly speaking, most of these procedures are based on the following protocol: in a solution containing various stabilizing agents (most often organic surfactants), precursor species (see Glossary) are introduced, which under the given reaction conditions start decomposing and form the so-called “monomer species” (see Glossary), which then react with each other, giving rise to nucleation of nanocrystals. These nuclei are then enlarged over time (i.e. they grow), upon further addition to them of the monomer species left in solution. The roles of organic stabilizers are: i) to slow down this growth process in a way that it can be controlled and the size of the crystals remains in the nano-size regime; ii) to coat efficiently the surface of the growing nanocrystals, so that they do not aggregate while growing; iii) in some cases to control the shape of the nanocrystals, by binding with different strengths to the various facets (see Glossary) of the nanocrystals, so that there could be substantial differences among the growth rates on said facets.

A major problem in the synthesis of nanocrystals with controlled sizes and shapes is that they present a large variation of these parameters in the sample, that is, the sample is often composed of various fractions of nanocrystals with different sizes (for example size distributions in spherical-shaped nanocrystals with standard deviations larger than 10%, or in the case of rod-shaped nanocrystals, diameter and length distributions with standard deviations larger than 10% and 20%, respectively) and also different shapes (for example, rods coexisting with spheres, platelets and other shapes). This can be a problem for several applications in which uniform nanoparticles are needed: examples are colloidal quantum dots/rods used as biological labels or as emitters in light emitting diodes, where the colour purity is strongly dependent on a narrow distribution of sizes. Another example in which uniform nanocrystals are needed is represented by applications where mono- or multilayers of semiconductor nanorods over large areas (mm² or even cm²) have to be prepared for photovoltaic devices or for diodes emitting linearly polarized light.

The major problem in preparing uniform nanocrystals is a poor control of the homogenous nucleation step, which often is prolonged over time, so that while some nanocrystals have nucleated and are already growing, other nanocrystals nucleate at a later time, which leads to a considerable spread in their size distribution. Various approaches have been developed so far in the synthesis of size-controlled and shape-controlled nanocrystals, which help to improve sample homogeneity to partially solve the above issue [1-7]. Examples are 1) secondary injections of precursors; 2) size/shape selective precipitation; 3) seeded growth. Seeded growth (or equivalently said “seed-mediated”) for example, yields nanocrystals with narrow distributions in terms of sizes (for example size distributions in spherical-shaped nanocrystals with standard deviations smaller than 5%, or in the case of rod-shaped nanocrystals, diameter and length distributions with standard deviations smaller than 5% and 10%, respectively) and also more uniform shapes.

For instance it has been demonstrated that shape-controlled nanocrystals of noble metals (Ag, Au, Pt) and of semiconductors can be fabricated using a seed-mediated approach [8] by which pre-formed nanocrystal seeds are mixed with reactants and eventually with surfactants which are facet-selective adsorbates. The seeds act as red-ox catalysts for metal ion reduction, so that their further growth is preferred over homogenous nucleation of additional particles. The process leads to nanorods, nanowires and also branched nanostructures. As another example of this seeded growth approach, for metal nanoparticles, it was recently demonstrated that starting from seeds having cubic shape, these seeds can be enlarged either to isotropic cuboctahedra or to nanorods [9] depending on the lattice mismatch between the seeds and material grown on top of them (cuboctahedra in the case of small lattice mismatch, nanorods in the case of large lattice mismatch).

As another example of seeded growth, reports have shown how in the case of semiconductor nanocrystals, rod- and tetrapod-shaped nanocrystals (see FIG. 1a, b) can be synthesized following the same “seeded growth” method. In that case, in a first step nanocrystals of a II-VI semiconductor (for example CdS, CdSe, CdTe, ZnSe, ZnTe), are synthesized [5, 6]. These can have a crystal habit (see Glossary) that is either spherical or tetrahedral or hexagonal prismatic, and are characterized by a narrow distribution of sizes/shapes. In a second step then, these nanocrystals are used as “seeds”, onto which a second material can be grown (for example CdS or CdSe, or CdTe), which yields shape-controlled semiconductor nanoparticles. If the crystal phase (see Glossary) of the initial seeds is hexagonal wurtzite, and also the “second” material grows in the hexagonal wurtzite phase, then this procedure can lead to the formation of rod-shaped semiconductor nanocrystals. If the material of the initial seed and the material used in the second step are the same (for example CdS or CdSe), nanorods of only one material are formed. If instead the two materials are different from each other, then the so-called “core-shell” nanorods are formed, each of them consisting of a thick rod-shaped “shell” encasing at its interior the original seed. One example is represented by CdSe(core)/CdS(shell) nanorods, which are often referred to in the literature as “dot-in-a-rod” nanocrystals.

Still referring to the case of “seeded grown” II-VI semiconductor nanocrystals, there are several reports in which the starting nanocrystal seeds are in the cubic sphalerite phase (often referred to as “zinc-blende” phase, although “sphalerite” is the correct definition) [5-6]. When a second semiconductor wurtzite material is grown on the seeds (for example CdS or CdSe, or CdTe), then the final morphology of the nanocrystals is a tetrapod. The tetrapod shape is rationalized by considering that sphalerite has tetrahedral symmetry, and it is generally believed that four of the {111} facets of a sphalerite nanocrystal are less reactive, namely the +{111} ones (meaning (1 1̅1̅), ( 1̅1 1̅), ( 1̅1̅1) and (111)), while the −{111} ones (meaning ( 1̅11), (1 1̅1), (11 1̅) and ( 1̅ 1̅ 1̅)) are more reactive and they promote nucleation of wurtzite pods, so that usually a tetrapod shape is finally obtained. Another rationalization of the tetrapod shape, which is quite not discussed in the literature, also because it was poorly understood, could be that the sphalerite nucleus has actually tetrahedral shape, that is only one group of four (111) facets is exposed, and there are the only four facets on which wurtzite pods can grow. Given the very small size of the seeds used so far in these types of syntheses, it was not simple to discern between tetrahedral shape and octahedral shape in them.

There are also numerous reports for the synthesis of nanocrystals with a higher number of pods, for example also the octapods (FIG. 1c). Octapods of various materials have been reported so far, namely CdS [10], CdSe [11], PbS [12], PbSe [13], Pt [14-15], FePt [16], and Cu₂O [17]. In most of the reported examples for octapods, the octapod shape arises as a result of the fast direct growth along the eight [111] directions (see Glossary) of a starting nanocrystal “seed”, when the crystal structure of the seed has octahedral symmetry, and the final branched nanocrystals are single crystalline domains. In octapods of CdS and CdSe, the pods have instead hexagonal wurtzite structure [11].

In the case of octapods-shaped nanocrystals of semiconductors, it was not clear up to now what were the specific reaction parameters that could govern the preferred formation of octapods over tetrapods, left aside whether the same fine level of control that had been achieved for tetrapods would be likewise possible for octapods. Also, octapod-shaped nanocrystals of all the materials mentioned above were until now obtained only by chance, with very low reproducibility, with low yields, uncontrolled growth, low selectivity and high polydispersity within the obtained multipods “population”. That is, the obtained nanocrystals exhibited a high heterogeneity, manifested by a broad distribution in terms of sizes with large fractions of non-octapod shaped by-products.

Another recent development in the synthesis of colloidal nanocrystals is the extension of cation exchange reactions, which are known to occur in many bulk ionic materials, to colloidal nanocrystals. In cation exchange, the sub-lattice of anions remains in place, while the cations of the cation framework are replaced by cations of another chemical species [18 and references therein]. Several reactions have been discussed in detail in various recent publications, and some of them are briefly outlined here. As an example, in both CdS and CdSe nanocrystals the Cd²⁺ ions can be replaced (in total or in part) by Cu⁺ or by Ag⁺ ions, to yield respectively Cu₂₋ₓSe, Cu₂₋ₓS, Ag₂Se and Ag₂S, respectively, and also the reverse reaction holds [18 and references therein]. Also CdSe(core)/CdS rod-shaped nanocrystals have been shown to undergo reversible cation exchange with Cu⁺, which preserves the core/shell structure of the initial nanocrystals. Cation exchange reactions have involved also Pb²⁺ ions [19].

### SUMMARY OF THE INVENTION

Scope of the present invention is to avoid the many drawbacks involved in the above described prior art methods for preparing octapod-shaped nanocrystals.

The invention is based on the discovery that one limitation in the prior art synthesis of octapod-shaped nanocrystals was the poor control of the “branching event”, that is, the early stage formation of the central region of the nanocrystals, namely the nucleation seeds. Specifically important is whether this “event” will result in a number of branches that is exactly 8 in all the nanocrystals present in the reaction environment, instead of a distribution of numbers of pods. Moreover uniform diameter and length in all 8 pods are equally important, rather than a non-uniform pod size distribution. The poor control of these stages were the main reasons of the drawbacks of the prior art methods, as indicated above.

The key innovation of the present invention with respect to previous reports lies in a process enabling, first of all, the achievement of uniform size- and shape-controlled nucleation seeds. These seeds consist of nanocrystals with eight {111} facets well developed in terms of surface area. The seeds exhibit preferably an octahedral habit, but also a truncated octahedral habit, and have a diameter larger than 5 nm range, normally in the 10-15 nm range, which are considered by the experts “large” nucleation seeds. This application firstly reports the synthesis of nanocrystals with these characteristics. Starting from these seeds with eight {111} facets well developed, each of these facets has the same probability of acting as nucleation site for the growth of a pod, unlike in the case of the well documented tetrapods where either only four {111} facets exist in the seed (the seed is a tetrahedron) or the pod growth occurs only on four {111} facets. Eventually, the process of the invention enables the production of octapod-shaped nanocrystals of various materials having controlled shape and chemical composition and with narrow distribution of the geometrical parameters such as size and pod length. In the current invention, the fraction of non-octapod shaped particles is less than 5% and the standard deviation of pod length is below 10%.

Accordingly, a first object of the invention is a process for the preparation of colloidal octapod-shaped nanocrystal comprising the following steps:
providing nanocrystal seeds of a material crystallized in a cubic phase and having eight developed {111} facets and diameter in the range of 5-20 nanometers;
contacting the nanocrystal seeds with a growth precursor to cause the seeded growth, on the eight {111} facets of the seed, of pods made of a material crystallizing in an hexagonal phase;
obtaining the octapod-shaped nanocrystals;

In an embodiment of the invention the nanocrystal seeds are instead prepared by: subjecting a first nanocrystal comprising a cation of a first element and having eight {111} facets to cation exchange reaction with cations of a second different element; obtaining said nanocrystal seeds comprising the cation of said second element.

In still another embodiment of the invention the process for the preparation of octapods further comprises the step of subjecting a first “generation” octapod to a partial or full cation exchange reaction.

A second object of the invention consists of colloidal octapod-shaped nanocrystals obtained by the process of the invention, having a core and eight pods, having non-octapod particle fraction lower than 5% and standard deviation of pods length below 10%.

A third object of the invention consists of the above mentioned octapod-shaped nanocrystals, when aggregated in a disordered way, in a porous film on a substrate.

A fourth object of the invention is a process for the preparation of a porous film of aggregated disordered octapod-shaped nanocrystals.

A further object of the invention consists of devices comprising the octapod nanocrystal or the film of disordered octapod-shaped nanocrystals of the invention wherein said device is an element of a photovoltaic cell, an electrode in Li⁺ ion batteries, an element of an ion sensor, a support for redox reaction, a nanocontainer or drug delivery agent, a filter membrane.

A still further object of the invention is a process for the preparation of nanocrystal seeds having eight developed {111} facets and diameter in the range of 5-20 nanometers.

### DESCRIPTION OF THE FIGURES

FIG. 1. Sketch illustrating a rod (a), a tetrapod (b), an octapod (c), and different shapes of nanocrystals: cube, octahedron, cuboctahedron (d).

FIG. 2. Transmission electron microscopy images of Cu₂₋ₓSe_{1-y}S_{1-y} alloy nanocrystals (a, b) which are cation exchanged using the method herein described yielding CdSe_{1-y}S_{1-y} alloys (c, d). The value of y (hence the anionic composition of the nanocrystals) stays unchanged during the cation exchange procedure.

FIG. 3. Sketch illustrating the seeded growth synthesis.

FIG. 4. TEM image of octapods obtained by the seeded growth synthesis and deposited on a carbon supported TEM grid. The preferential positioning with four pods touching the substrate results in a “Greek cross” shape in its projection. Note the high monodispersity in octapod dimensions and the low content of extra nano-objects (rods, tetrapods, or other shaped nanoparticles).

FIG. 5. High resolution images (HRTEM) of an octapod, viewed along the zone axis of the core. The pods have a wurtzite structure, while in the central part (where the pods become progressively thinner) the cubic structure of the core is visible, as enlarged in the inset, showing the corresponding reflections from its Fourier transform.

FIG. 6. a) Chemical map obtained from S-L_{2,3} and Se-L_{2,3} filtered maps (EFTEM), revealing the presence of the CdSe core at the centre of the octapods with CdS pods. b) STEM-EDS line profile across one octapod (scan direction as the white arrow in the left panel). The chemical composition is consistent with CdSe cores and CdS pods.

FIG. 7. 3D reconstruction of an octapod from STEM projections. Note the octapod can be thought of as consisting of two tetrahedrons: (a) one with flat tip ends, (b) one with pointed tip ends.

FIG. 8. a) Absorption spectra of the original Cu₂₋ₓSe seeds and the CdSe nanocrystals obtained by the previously mentioned cation exchange reaction. Additionally, the band edge emission of the CdSe nanocrystals is shown. b) Absorption and emission spectra of the octapods consisting of a CdSe core and CdS pods.

FIG. 9. EFTEM images of two octapod nanoparticles at first stage of cation exchange. a) Elastic filtered image. b-d) S-L_{2,3}, Cd-M_{4,5}, and Cu-L_{2,3} elemental maps respectively, showing the distribution of these elements in the octapod heterostructures (the contour of the octapods from panel a is traced for clarity).

FIG. 10. HRTEM images of the pods of octapods at first stage of cation exchange. a) a general view of an octapod nanoparticle observed along a non specific [hkl] zone axis; b) detail of hcp CdS pod grown along its [0002] crystal direction showing the (0 0 0 2) lattice planes with d-spacing of 3.34 Å, on the tip of the pod is nucleated a hcp Cu₂S nanocrystal displaying the (1 0 1̅ 2) lattice planes with spacing of 2.42 Å; c) hcp CdS pod showing the (1 0 1̅ 0) and (0 1 1̅ 3) lattice planes with spacing of 3.56 Å and 1.89 Å respectively, the insets display hcp Cu₂S nanocrystals grown on the tip of CdS.

FIG. 11. Partially cation exchanged octapods. a) HRTEM of pods showing two hexagonal regions, a first close to the core still rich in Cd, and a second fully exchanged in Cu₂S. The core region consists of CdSe, as confirmed by the EDS chemical profiles in b).

FIG. 12. (a) HRTEM image of an octapod after full cation exchange showing the lattice sets (220) of the cubic Cu₂Se core and the crystal lattice sets (1 1 2̅ 0) of the hexagonal Cu₂S pods. (b) EDS elemental composition of an octapod measured along the dashed line revealing the different chemical composition of the pods and the core.

FIG. 13. Scanning electron microscopy images of thin films of octapods deposited on SiO₂ substrates that underwent no treatment after deposition (a), after annealing under N₂ atmosphere at 200° C. for 20 min (b), and after hydrazine treatment and annealing (c-d).

FIG. 14. Typical photocurrent spectra of a porous octapod film recorded at T=9.5K (filled circles) and T=300K (open circles), plotted together with the optical absorption (grey line) at 300K. The strong onset at 485 nm in both cases corresponds to the absorption from the CdS pods. The weak onset in the absorption spectrum around 700 nm and the small peak in the room temperature photocurrent spectrum correlate with the band gap of the CdSe cores. The gradual decrease of the absorption spectrum between 500 nm and 700 nm can be attributed to Rayleigh scattering of the incident light on micron size grains in the octapod film. The dotted lines indicate the peaks, which were used to extract the band gap of the octapod pods and core. The spectra are shifted vertically for clarity.

FIG. 15. a) SEM image of a disordered film of octapods nanocrystals on a silicon wafer obtained by solvent evaporation. b) Higher magnification of the sample showing amorphous arrangement of the octapods in the film. c) Same region of the sample in a) after Cd²⁺ to Cu⁺ cation exchange performed directly on the deposited film, and demonstrating the film maintains its original morphology. d) Higher magnification from a region after cation exchange, displaying close similarities with the pristine sample in b). d) Same region of the sample in c) after additional oxygen plasma treatment. e) Higher magnification from a region after plasma treatment. The octapods are surrounded by an oxide shell (making the pods thicker), that welds the tips of the pods when they are very close each other (the white arrow points to one of these events).

### DETAILED DESCRIPTION OF THE INVENTION

### Glossary

The following expressions are used in the present specification with the indicated meaning.

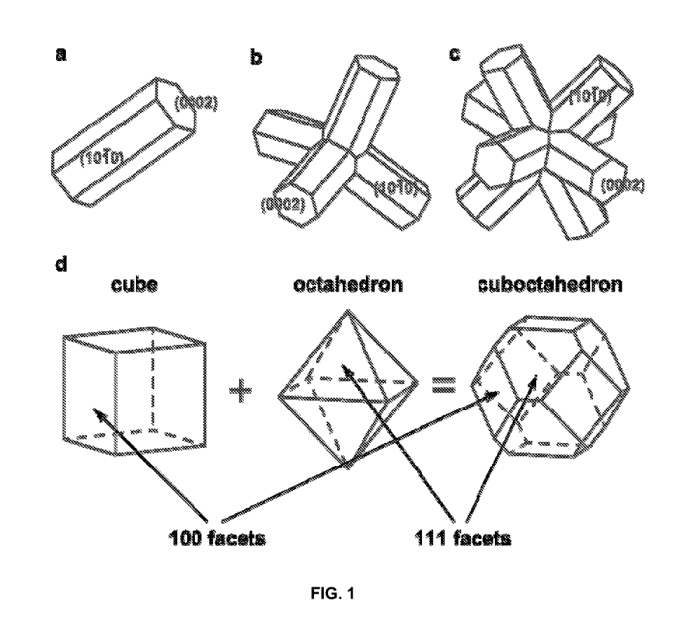

The expressions “habit” and “shape” can be used as synonyms, in particular they refer to the actual morphology of an object (the seed); examples of shape are cubic, octahedral, cuboctahedral, truncated octahedral etc. An example of habit is the crystal habit. See FIG. 1d.

The term “phase” defines a state of aggregation of matter, made of a disposition of atoms or molecules in the three-dimensional space, and characterized by relatively uniform chemical and physical properties. Such disposition of atoms and molecules can be disordered or follow a regular repetition according to different periodicities and symmetries.

The term “structure” refers to the arrangement of atoms or molecules which are repeated periodically in three-dimensional space according to three non-coplanar axes along which are defined three vectors that describe the unit cell. In our case, the structure of the pristine seeds is cubic. In one embodiment, the structure of the pristine seeds is cubic berzelianite, as after transformed into CdSe sphalerite, while the pods have hexagonal wurtzite structure.

The term “symmetry” defines the geometrical operations that transform an object or a structure into itself. From this point of view the cube, octahedron, cuboctahedron and truncated octahedron have the same symmetry.

To indicate a family of lattice “planes” of a cubic crystal structure, we use the notation (h k l), while [h k l] is used to indicate the “direction” that is normal to this family of planes. This set of h k l indices is referred to as “Miller indices”. In the case of the hexagonal structure, we use the notation (h k i l) and [h k i l] for the family of planes and its normal direction (these are the so-called “Miller-Bravais indices”), respectively.

The term “facets” refers to the flat terminations or surfaces of a crystal or a nanocrystal, and may have all possible equivalent orientations (given by the surface normal directions, indicated by the Miller or Miller-Bravais indices). In particular “{111} facets” refers to the eight faces of an octahedral, cuboctahedral, and truncated octahedral nanocrystal with cubic structure (see FIG. 1d).

The term “chemical precursor” or, equivalently stated, “precursor”, or yet “precursor species”, refers to a chemical species containing at least one of the elements needed to nucleate/grow the seeds and/or the pods. When precursors are introduced in the reaction environment, as a consequence of the high temperature and of the presence of surfactants, they are in general decomposed and they are transformed into other reactive chemical species, the so-called “monomers” or, equivalently stated, “monomer species”, that actually interact with the seeds and nucleates the pods, or reacts with the growing pods and further contribute to their growth, in both cases depositing atomic species.

### The Process

The process of the invention comprises two essential steps:

1) Synthesizing large colloidal nanocrystal “seeds” in a cubic phase having 8 well developed {111} facets, meaning that the surface area of each (111) facet is at least 1 nm².
2) Growing the “pods” of a material crystallizing in a hexagonal crystal phase onto the seeds, each pod growing on one of the eight {111} facets of the seed, with its [0001] direction parallel to one of the [111] directions of the seed. (Henceforth, the 4-index Miller-Bravais notation will be used for naming crystallographic planes and directions of the wurtzite pods).
3) Optionally, the “as-synthesized” octapods are then subjected to a cation exchange procedure, that is, they can be converted totally or partially into octapods of other materials upon cation exchange or via an oxidation reaction, the latter possible also via an oxygen plasma treatment.

### Step 1: the Seeds

The nanocrystal seeds suitable for the present invention are large nanocrystal with uniform sizes, and larger than 5 nm, for instance in the 10-15 nm range, and having 8 well developed {111} facets. The seed crystals are in a cubic phase and have preferably an octahedral shape, but alternatively can also have a truncated octahedral shape or cuboctahedral shape.

The seeds are synthesized as described in the examples, from any material for which a shaped controlled procedure is known and well developed in the art. Examples of synthesis of large (i.e. larger than 5 nm) octahedral-shaped seeds of PbSe (i.e. a II-VI semiconductor crystallized in a cubic phase) can be found in ref. [20]; examples of synthesis of large cuboctahedral-shaped seeds of cubic Cu₂₋ₓSe can be found in ref. [21]. Other examples of syntheses of large (i.e. larger than 5 nm) nanocrystals crystallized in a cubic phase and with well developed {111} facets are: ref. [22] for Cu₂O, ref. [23] for MnO, ref. [24] for PbS, ref. [25] for YF₃, ref. [26] for In₂O₃.

The seeds consist of or comprise a material, either elemental or compound, selected from the group comprising:

A group IV semiconductor crystallized in a cubic phase, a group III-V semiconductor crystallized in a cubic phase, a IV-VI semiconductor crystallized in a cubic phase, a II-VI semiconductor crystallized in a cubic phase, a single-element material crystallized in a cubic phase, a multi-metallic material crystallized in a cubic phase, an oxide of one or more elements crystallized in a cubic phase, or one material not comprised in the above groups and being selected from Cu₂Se, Cu₂₋ₓSe, Cu₂₋ₓSe_{1-y}S_{y}, Cu₂S, Cu_{2.86}Te, Ag₂Se, AgSe, Ag₂S, Ag₂Te, CoSe, CoSe₂, CoS₂, CoTe₂, Co₃Se₄, Co₉S₈, ZnSO₄, SeS, MnSe, MnSe₂, MnS, MnSe₂, MnTe₂, MnS_{1-y}Se_{y}, MnSe_{1-y}Te_{y}, SiC (3C), SiGe, CuIn₁₋ₓGaₓSe₂, Zn₃As₂, Li₃NbO₄, La₂CuO₄, Ga₄Se₈, Ga_{1.33}Se₂, MnₓIn₁₋ₓAs, CdₓMn₁₋ₓTe, Mn_{0.4}Pb_{3.6}Te₄, CuInₓGa₁₋ₓSe₂, CuInSe₂, Ag_{0.28}Ga_{2.56}S₄, YF₃.

In an embodiment of the invention the nanocrystal seeds are chalcogenides or oxides of any suitable elements capable to form a stable compound with the chalcogenide or with oxygen.

Particularly suitable nanocrystal seeds for the invention are sphalerite CdSe nanocrystals of octahedral, cuboctahedral, or truncated octahedral habit.

In a specific embodiment of the invention the starting nanocrystal seeds are colloidal Cu₂₋ₓSe nanocrystals, with “x” ranging from 0 to 0.40. Preferably, these seeds are in the cubic berzelianite phase, having uniform sizes and diameters ranging from 10 to 15 nm. Alternatively, the starting material can be an alloy such as Cu₂₋ₓSe_{1-y}S_{y}, or CdSe_{1-y}S_{y}, for instance Cu_{1.94}Se_{0.69}S_{0.31}, Cu_{1.98}Se_{0.55}S_{0.45}, CdSe_{0.72}S_{0.28}, CdSe_{0.47}S_{0.53}.

### Cation Exchange Reaction on the Seeds

Provided that the nanocrystal seed material of the invention comprises at least one cation species, the chemical characteristics of the nanocrystal seeds of the invention can be modified by partial or full cation exchange reaction.

A key feature of all cation exchange reactions in nanocrystals is that they preserve the shape of the original nanocrystals. This can be used advantageously for synthesizing nanocrystals in shapes that at present are not directly accessible via direct chemical synthesis (i.e. via nucleation and growth alone). As an example, one can first synthesize nanocrystals of a material for which shape-control procedures are well developed, and then subject the nanocrystals to a cation exchange reaction that yields the desired material, if indeed the second material can be accessed from the first material by a cation exchange reaction. Using the same concept, one can even subject a first material to a sequence of cation exchange reactions: a nanocrystal of material 1 can be cation-exchanged to a nanocrystal of material 2 (preserving its original shape), and material 2 can be cation-exchanged to material 3 (again preserving its original shape). This latter procedure is particularly useful if for example material 1 cannot be cation-exchanged to material 3 directly.

Accordingly, the starting nanocrystal seeds are subjected to a cation exchange reaction by contacting the nanocrystals comprising a first cation with a chemical species releasing a second different cation. This cation derives from a material, either elemental or compound, selected from the group comprising:

A group IV semiconductor crystallized in a cubic phase, a group III-V semiconductor crystallized in a cubic phase, a IV-VI semiconductor crystallized in a cubic phase, a II-VI semiconductor crystallized in a cubic phase, an oxide of one or more elements crystallized in a cubic phase, or one material not comprised in the above groups and being selected from Cu₂Se, Cu₂₋ₓSe, Cu₂₋ₓSe_{1-y}S_{y}, Cu₂S, Cu_{2.86}Te, Ag₂Se, AgSe, Ag₂S, Ag₂Te, CoSe, CoSe₂, CoS₂, CoTe₂, Co₃Se₄, Co₉S₈, ZnSO₄, SeS, MnSe, MnSe₂, MnS, MnSe₂, MnTe₂, MnS_{1-y}Se_{y}, MnSe_{1-y}Te_{y}, SiC (3C), SiGe, CuIn₁₋ₓGaₓSe₂, Zn₃As₂, Li₃NbO₄, La₂CuO₄, Ga₄Se₈, Ga_{1.33}Se₂, MnₓIn₁₋ₓAS, CdₓMn₁₋ₓTe, Mn_{0.4}Pb_{3.6}Te₄, CuInₓGa₁₋ₓSe₂, CuInSe₂, Ag_{0.28}Ga_{2.56}S₄, YF₃.

Likewise, the material of the first seed nanocrystal can be a material of the above list.

Example of chemical species releasing cations are metal alkylphosphonates, alkyl carboxylates, or species like for example tetrakis(acetonitrile)copper(I) hexafluorophosphate.

Starting seeds, which can advantageously be subjected to cation exchange, are anyone of those described above, for example Cu₂₋ₓSe, or an alloy such as Cu₂₋ₓSe_{1-y}S_{y}, or CdSe_{1-y}S_{y}, for instance Cu_{1.94}Se_{0.69}S_{0.31}, CU_{1.98}Se_{0.55}S_{0.45}, CdSe_{0.72}S_{0.28}, CdSe_{0.47}S_{0.53}.

For example, berzelianite Cu₂₋ₓSe nanocrystals are converted by the addition of Cd²⁺ cations into CdSe nanocrystals in the cubic sphalerite phase. This conversion maintains the habit of the berzelianite Cu₂₋ₓSe nanocrystals, thus the sphalerite CdSe nanocrystals have an octahedral habit, or truncated octahedral habit, with a diameter larger than 5 nm.

Sphalerite CdSe nanocrystals with diameters larger than 5 nm range could till now not be produced by any other procedure than the cation exchange procedure presented here. Hence, the intermediate formation of these sphalerite CdSe seeds with eight {111} facets well developed is the key point for the subsequent growth of octapod shaped nanocrystals.

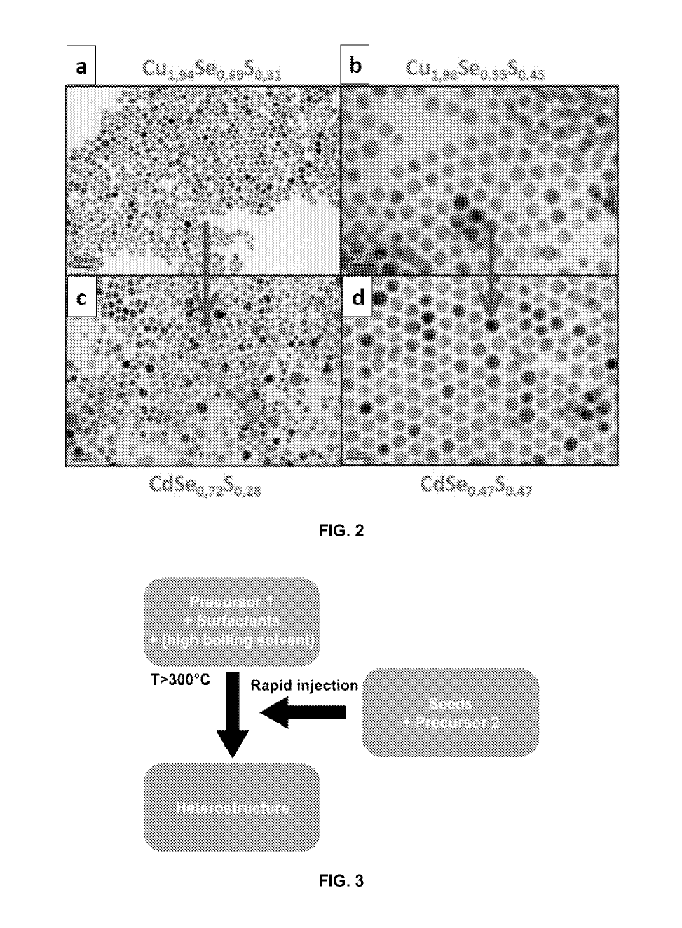

Yet, not only binary components like Cu₂₋ₓSe can be cation exchanged. Also e.g. alloyed components like Cu₂₋ₓSe_{1-y}S_{y} can undergo cation exchange reactions in which the anionic composition and shape remain the same (thus yielding e.g. CdSe_{1-y}S_{y} with the same y value as the Cu₂₋ₓSe_{1-y}S_{y} nanocrystals they were made from), which can give access to structures that are not accessible by other procedures (FIG. 2). Therefore starting materials for the process of the invention can also be the aforementioned alloys.

It is worth to note that the cation exchange reaction is a reversible process enabling the replacement of a cation or the restoration of an original cation at any stage of the octapod preparation process. That is, either on the nucleation seeds or on the as synthesized octapod crystals, as will be disclosed below.

Although not necessarily, the success of the cation exchange reaction may depend on the presence in the reaction medium of suitable surfactants or mixture thereof. Examples of surfactants suitable for the present invention are alkylphosphines, alkylphosphine-oxides, alkylphosphonic acids, alkylamines, fatty acids or alkanes, alkenes, aromatic compounds and ethers. Specific examples are: trioctylphosphine (TOP), trioctylphosphine oxide (TOPO), octadecylphosphonic acid (ODPA), hexylphosphonic acid (HPA), oleylamine (OLAM), oleic acid (OLAC).

For instance, in a typical cation exchange reaction, Cu₂₋ₓSe nanocrystals are dissolved in trioctylphosphine (TOP). Equally, Cd²⁺ ions are preferably used in the form of cadmium alkylphosphonate, for example a mixture of hexyl- and octadecyl-phosphonate in trioctylphosphine oxide (TOPO), or in the form of cadmium oleate.

Suitable solvents for the reaction are the same surfactants seen above or are e.g. 1-octadecene and various other organic solvents with a boiling point higher than the reaction temperature, for example squalane or alkyl ethers.

The reaction is performed at temperature between 100° C. and 400° C., for instance 300° C., 320° C. or 350° C., for a time between 1 and 10 min. However, several tests have shown that the reaction is mainly completed after 1 min if, for example, the exchange is done at 300° C., and longer reaction time does not significantly influence the final product. Also, room temperature reactions can also be carried out, but these can take up to several hours for some compounds.

After the cation exchange reaction, the nanocrystals may be maintained in reaction solution/dispersion and further processed in the subsequent step (i.e. seeded growth). Alternatively they can be washed by repeated precipitations by addition of a suitable solvent, for instance methanol or ethanol, and re-dispersed in a non-polar or moderately polar solvent, for example toluene, chloroform, hexane or generally a solvent of aliphatic or aromatic halogenated or non-halogenated nature. In view of the subsequent step of seeded growth, the nanocrystals, after the last washing step, can be dispersed in a suitable surfactant, for example in trioctylphosphine (TOP), or in a solvent, for example toluene, chloroform, hexane or generally a solvent of aliphatic or aromatic halogenated or non-halogenated nature. The obtained nanocrystals with diameters larger than 5 nm are relatively uniform and the sample has a narrow particle size distribution. Starting from Cu₂₋ₓSe, XRD analysis can be used to confirm that the final product is sphalerite CdSe nanocrystals.

### Step 2, the “Seeded Growth”

At the basis of the “seeded growth” approach is the well-know evidence, from crystal growth theory, that the activation energy for heterogeneous nucleation (i.e. nucleation of a crystal on top of a pre-existing surface/seed) is much lower than that for homogeneous nucleation (i.e. nucleation of a crystal in the absence of a pre-existing surface/seed). Therefore, in the “seeded growth” approach, pre-formed seeds are present in the reaction environment. Then chemical precursors are introduced in the reaction environment, where they decompose and form the monomer species, which actually cause the nucleation and growth of the pods, as described in the Glossary section. In the present case, the monomer species are indeed deposited preferentially onto the seeds (heterogeneous nucleation) rather than forming separate nuclei in solution (homogeneous nucleation). As the homogeneous nucleation is by-passed by the presence of the seeds, all nanocrystals undergo practically identical growth conditions since their formation, and therefore they maintain a narrow distribution of sizes and shapes during their evolution (see FIG. 3).

Thus, starting from big nucleation seeds having eight {111} facets, being well developed in terms of surface area, each of these facets has the same probability of acting as nucleation site for a pod growth. Each pod, having hexagonal crystal phase, grows on one of the eight {111} facets of the seed, with its [0001] direction parallel to one of the [111] directions of the seed. The complete crystallographic relationships between the seed and each pod are: seed{111}//pod{0002} and seed [2 1̅1̅]//pod [10 1̅0](the first relationship defines the planar interface alignment, the second the vector alignment, and together they fully describe the epitaxial growth relationship between each pod and the seed of the octapod).

The precursors for growing the pods are chemical species containing at least one of the elements needed to nucleate/grow the seeds and/or the pods. When precursors are introduced in the reaction environment, as a consequence of the high temperature and of the presence of surfactants, they are in general decomposed and they are transformed into other reactive chemical species, the so-called “monomers” or, equivalently stated, “monomer species”.

For example, typical chemical precursors are cadmium oxide (CdO) and hexamethyldisilathiane. When CdO is introduced in the reaction environment, it is decomposed for example by a phosphonic acid at high temperature and forms a cadmium phosphonate. Hexamethyldisilathiane on the other hand decomposes and frees sulfur species. Both cadmium phosphonate and these sulfur species for example can be identified as the chemically reactive species (i.e. the “monomer”) that actually interact with the seeds and nucleates the pods, or reacts with the growing pods and further contributes to their growth, in both cases depositing Cd and S species, respectively. Also the seeds are synthesized using suitable chemical precursors, as described in the “EXAMPLES” section.

The growth precursors generating the various compounds are well known in the art and the skilled person can retrieve the necessary information from the literature.

By way of example, some typical precursors for a II-VI semiconductor are listed hereinafter:

### CdX (X═S, Se, Te)

For Cadmium: A cadmium salt or an oxide (for example cadmium nitrate, or cadmium acetate or cadmium oxide), or an organometallic compound (for example dimethylcadmium).
For the chalcogen: the chalcogen in its elemental form (i.e. S, Se, Te) or as organometallic compound, for example bis(trimethylsilyl)sulfide, bis(trimethylsilyl)selenide, bis(trimethylsilyl)telluride, thiourea, selenourea, tellurourea), trioctylphosphine sulfide, trioctylphosphine selenide, trioctylphosphine selenide, or a suspension of the elemental form dispersed in a weekly coordinating solvent such as 1-octadecene.
Examples of single source precursors: bis(dialkyldithio-/diseleno-carbamato)cadmium(II).

### ZnX (X═S, Se, Te)

For Zinc: A zinc salt or an oxide (for example zinc nitrate, or zinc acetate or zinc stearate or zinc oxide), or an organometallic compound (for example diethylzinc).
For the chalcogen: the chalcogen in its elemental form (i.e. S, Se, Te) or as organometallic compound, for example bis(trimethylsilyl)sulfide, bis(trimethylsilyl)selenide, bis(trimethylsilyl)telluride, thiourea, selenourea, tellurourea, trioctylphosphine sulfide, trioctylphosphine selenide, trioctylphosphine selenide, or a suspension of the elemental form dispersed in a weekly coordinating solvent such as 1-octadecene.
Examples of single source precursors: bis(dialkyldithio-/diseleno-carbamato)zinc(II)

### Cu_{y}X (X═S, Se, Te)

For Copper: A copper salt (for example copper nitrate, or copper acetate or copper chloride)
For the chalcogen: the chalcogen in its elemental form (i.e. S, Se, Te) or as organometallic compound (for example bis(trimethylsilyl)sulfide, bis(trimethylsilyl)selenide, bis(trimethylsilyl)telluride, thiourea, selenourea, tellurourea).

Wurtzite GaP (Example of a III-V nanocrystal forming in an hexagonal phase): a single source precursor can be used here: tris(di-tert-butylphosphino) gallane (Ga(PBu₂)₃).

The precursors for growing the pods are chosen as to generate materials, either elemental or compound, that can crystallize in an hexagonal phase, for example, one of the following materials: a group IV semiconductor crystallizing in an hexagonal phase, a group III-V semiconductor crystallizing in an hexagonal phase, a IV-VI semiconductor crystallizing in an hexagonal phase, a II-VI semiconductor crystallizing in an hexagonal phase, a single element material crystallizing in an hexagonal phase, an oxide of one or more elements crystallizing in an hexagonal phase, or one material not comprised in the above groups and being selected from Cu₂S, Cu₂₋ₓS, CuSe, Cu₂Te, Cu₂₋ₓSe_{1-y}S_{y}, Cu₂ZnSnS₄, CuS, Se, Co, CoSe, CoTe, CoS, Ag₂Se, MnS MnTe, MnSe, MnTe_{1-y}Se_{y}, SiC (4H, 6H), Sb, AsSb, SbN₉, Zn_{3.83}Sb₃, Bi₂Te₃, CdSb, LiNbO₂, LiNbO₂, PbI₂ MoSe₂, As_{0.5}Ga_{0.5}Mn₂, AsMn, Ag_{0.144}Ga_{1.286}^{S}₂, Pt₂Si₃, Pt₂Si.

It is indeed possible that some materials can crystallize either in the cubic or in the hexagonal phase. Which phase will actually form in the growth environment can be decided based on the reaction conditions, namely temperature, surfactant, solvent. So, in principle the skilled person is well aware of or in any case can easily find in literature, the conditions that lead to crystallization of a material that exhibits polymorphism either in the cubic or in the hexagonal phase.

In a specific embodiment of the invention the precursors will nucleate and grow pods of the following materials: chalcogenides or oxides of any elements capable to form a stable compound with the chalcogenide or with oxygen.

Particularly suitable are cadmium chalcogenides such as CdSe or CdS, each used alone.

The pods formed by contacting the seeds with precursors for either “CdS” or “CdSe” will grow in the wurtzite crystal phase, normally with shapes resembling hexagonal prisms.

The seeded growth step is carried out in the presence of suitable surfactants or mixture thereof, which also act as reaction solvent and which are those indicated above as suitable for the cation exchange reaction. For instance, the nanocrystal seeds can be dispersed in TOP together with one or more precursors, while one or more precursor may be dissolved in a mixture of surfactants such as TOPO, HPA and ODPA.

Other solvent suitable for the seeded growth are e.g. octadecene or any solvent with a boiling point higher than the reaction temperature.

The octapod growing step runs for 1 to 10 min, mainly 5 or 7 min operating at temperature between 280° C. and 380° C. The step is carried out under inert atmosphere, for instance under nitrogen or argon atmosphere.

The step-by-step process (two pot procedure) describe above, characterized by the subsequent preparation of the nucleation seeds (step 1) and the growth of the pods through the seeded growth (step 2) may be replaced by a one-stage process (one-pot procedure) by in situ ion exchange followed by seeded growth, as illustrated below and in the examples.

### Synthesis of Octapods by In Situ Ion Exchange (“One Pot Procedure”) Followed by Seeded Growth:

A first solution is prepared, which contains previously synthesized nanocrystal seeds and precursor for the anion of the pod material, in a suitable solvent, at defined concentration.

This solution is injected into a reaction flask containing a mixture of surfactants and a precursor releasing a different cation, and then heated at a specified temperature under inert atmosphere. The solvents, the chemical species releasing the cation, and the surfactants are the same as described above. After the injection, the resulting solution is allowed to recover at the pre-injection temperature for at least 3 min, after which it is cooled to room temperature (see table 1 for details).

If necessary, this solution is washed by repeated precipitations (via addition of polar solvent) and re-dissolution in less polar solvent. The as-synthesized octapods are stored under nitrogen inside the glove box. Compared to known procedures, this is the only procedure combining cation exchange and a seeded growth procedure in one reaction.

### Step 3: Octapods Cation Exchange

The chemical/physical characteristics of the “first generation” of synthesized octapods nanocrystals may be modified by cation exchange reaction.

The cation exchange reaction of the as-synthesized octapod nanocrystals may be performed according to the method described in WO-A2-2009/009514 or EP-A-2268570 for the preparation of nanorods.

Since the cation exchange is both a repeatable and reversible reaction, the “as-synthesized” octapod-shaped nanocrystals can themselves be subjected to a cation exchange procedure. That is, they can be converted totally or partially into octapods of other materials upon cation exchange. Depending on the operating conditions, this reaction enables either the total cation exchange of the octapods, with replacement of the cation species both in the pods and in the core with different cations, or a partial cation exchange producing binary heterostructures, wherein core and pods consist of different materials, or also ternary or complex heterostructures, in which the pods may consist of segments of two or more different materials.

The total cation exchange is achieved operating with an excess, while the partial cation exchange with a defect, of the exchanging cation. Also in this case, the exchanging cation is preferably (but not exclusively) selected from the above indicated list of materials suitable for the cation exchange reaction of the seed and the pods. The conditions of the cation exchange reaction are as described above and in the examples.

### Partial Cation Exchange on Octapods

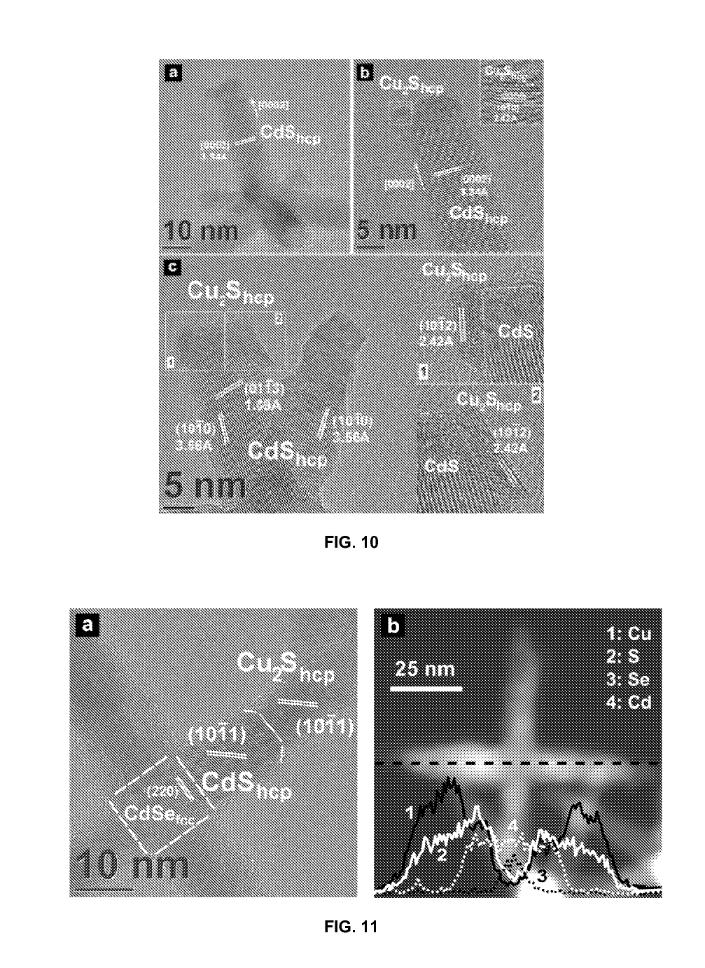

By using an amount of exchanging cationic precursor in defect as compared to the amount of octapods, it is possible to perform only a partial exchange. For example, treating CdSe/CdS octapods with the Cu⁺ ions in defect, the extent of the conversion of the Cd-based octapods into Cu-based octapods depends on the amount of Cu salt that was used for the synthesis (FIGS. 9, 11). During the partial ion exchange, the core of the octapod does not take part in the reaction while the pods undergo selective ion replacement. The reaction starts at the tips of the octapods pods where the second cation, e.g. Cu⁺ ions, replaces the first cation, e.g. Cd²⁺ ions, and Cu₂S is formed (FIGS. 9, 10). Subsequently, the ion exchange reaction extends towards the core of the octapods, increasing the amount of Cu₂S phase and thus reducing the CdS volume. When the reaction is stopped at this stage, a new ternary compound is formed which consists of a core of CdSe and pods consisting of CdS (in the region close to the core) and Cu₂S (in the region close to the tip of each pod) (FIG. 11).

Hence, by tuning the amount of added precursor for cation exchange, the volume of the converted material of the pods (preferably starting from the tip of the pod) can be fine tuned from almost zero to complete conversion of the pod material into another material.

A list of octapods that can be accessed by the above approach by choosing the correct cation exchange precursor, comprises all the octapods whose materials of the seeds(cores) and materials of the pods have been described above.

Furthermore, upon controlled oxidation of the various nanocrystals, the corresponding oxide nanocrystals are obtained.

Due to the fact that the cation exchange starts preferably from the tips of the pods and proceeds subsequently towards the center (with more and more cation exchange precursor used) it is also possible to obtain segmented multi-component pods by adding different cation exchange precursors subsequently. For example, it is possible to obtain an octapod made from a CdSe core and pods that are made of CdS close to the core, due to a first cation exchange reaction and yet another material at the tip region of the pod, which can again be selected from the above mentioned materials and which is generated in a second partial cation exchange reaction.

Other examples of such segmented structures are: CdSe(core)/CdS(segment1)/Cu₂S(segment2)/PbS(segment3), CdSe(core)/CdS(segment 1)/Cu₂S(segment 2)/ZnS(segment 3) and similar ones. So these are quaternary octapods.

### Total Cation Exchange of the Octapods

When an excess of the exchanging cation precursor, compared to the amount of octapods, is used, the result is a full replacement of cations both in the core and in the pods, which however preserves the shape of the octapod. For example, using an excess of Cu precursor compared to the amount of CdSe/CdS octapods, the result is a full replacement of the Cd²⁺ by Cu⁺ cations, thus yielding a Cu₂₋ₓSe (core)/Cu₂S(pods) octapod structure.

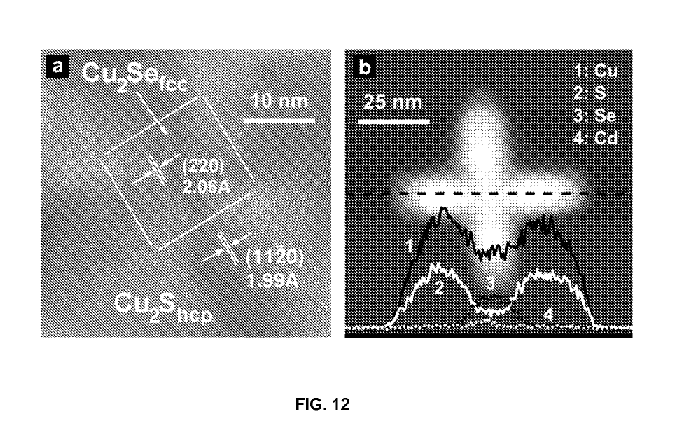

HR-TEM analysis of nanoparticles after cation exchange reveals heterostructures which still exhibit octapod habit (FIG. 12). In particular crystallographic and chemical data analyses confirm the presence of a core region of cubic berzelianite (Cu₂₋ₓSe), showing (220) and (200) lattice planes (FIG. 12a). FIG. 12b shows the elemental composition of an octapod measured along a profile using energy dispersive spectroscopy (EDS), which reveals the different chemical composition of the pods and the core. The lines correspond to the following elements: 1:Cu, 2:S, 3:Se, 4:Cd.

A very similar procedure is applied in order to obtain Ag based octapods: using an excess of Ag⁺ precursor, it is possible to exchange Cd²⁺ cations by Ag⁺, which yields Ag₂Se(core)/Ag₂S(pods) octapods.

It is worth to note that the complete cation exchange from Cd based octapods to Cu or Ag cation based octapods also demonstrates the reversibility of the ion exchange reaction, which was used to obtain the octapods in the first place. That means that, starting from a Cu₂₋ₓSe seed, CdSe(core)/CdS(pods) octapods were produced, via an intermediate (in situ) Cu⁺ to Cd²⁺ ion exchange step. Upon complete cation exchange of the whole octapod, the core region is transformed back into Cu₋ₓSe yielding Cu₂Se/Cu₂S octapods which have a core made of the original Cu₂₋ₓSe nanoparticles.

The Octapod Nanocrystals and their Characterization

The process of the invention enables the production of octapod-shaped nanocrystals of various materials having controlled shape and chemical composition and with narrow distributions of the geometrical parameters such as the shape and size of the crystals and the number and length of pods. In particular, the fraction of non-octapod shaped particles, in the nanocrystal populations of the invention is less than 5% and the standard deviation of pod length is below 10% (See section on characterization). Materials obtainable according to the present invention are colloidal octapod-shaped nanocrystals having the core made of a material crystallized in a cubic phase and the pods made of a material crystallizing in an hexagonal phase.

The core consists of or comprises a material crystallized in a cubic phase selected from:

A group IV semiconductor crystallized in a cubic phase, a group III-V semiconductor crystallized in a cubic phase, a IV-VI semiconductor crystallized in a cubic phase, a II-VI semiconductor crystallized in a cubic phase, a single-element material crystallized in a cubic phase, a multi-metallic material crystallized in a cubic phase, an oxide of one or more elements crystallized in a cubic phase, or one material not comprised in the above groups and being selected from Cu₂Se, Cu₂₋ₓSe, Cu₂₋ₓSe_{1-y}S_{y}, Cu₂S, Cu_{2.86}Te, Ag₂Se, AgSe, Ag₂S, Ag₂Te, CoSe, CoSe₂, CoS₂, CoTe₂, Co₃Se₄, Co₉S₈, ZnSO₄, SeS, MnSe, MnSe₂, MnS, MnSe₂, MnTe₂, MnS_{1-y}Se_{y}, MnSe_{1-y}Te_{y}, SiC (3C), SiGe, CuIn₁₋ₓGaₓSe₂, Zn₃As₂, Li₃NbO₄, La₂CuO₄, Ga₄Se₈, Ga_{1.33}Se₂, MnₓIn₁₋ₓAs, CdₓMn₁₋ₓTe, Mn_{0.4}Pb_{3.6}Te₄, CuInₓGa₁₋ₓSe₂, CuInSe₂, Ag_{0.28}Ga_{2.56}S₄,YF₃.

The pods consists of or comprises a material crystallized in a hexagonal phase selected from:

a group IV semiconductor crystallizing in an hexagonal phase, a group III-V semiconductor crystallizing in an hexagonal phase, a IV-VI semiconductor crystallizing in an hexagonal phase, a II-VI semiconductor crystallizing in an hexagonal phase, a single element material crystallizing in an hexagonal phase, an oxide of one or more elements crystallizing in an hexagonal phase, or one material not comprised in the above groups and being selected from Cu₂S, Cu₂₋ₓS, CuSe, Cu₂Te, Cu₂₋ₓSe_{1-y}S_{y}, Cu₂ZnSnS₄, CuS, Se, Co, CoSe, CoTe, CoS, Ag₂Se, MnS MnTe, MnSe, MnTe_{1-y}Se_{y}, SiC (4H, 6H), Sb, AsSb, SbN₉, Zn_{3.83}Sb₃, Bi₂Te₃, CdSb, LiNbO₂, LiNbO₂, PbI₂ MoSe₂, As_{0.5}Ga_{0.5}Mn₂, AsMn, Ag_{0.144}Ga_{1.286}S₂, Pt₂Si₃, Pt₂Si.

In a specific embodiment of the invention, the core and the pods may be chalcogenides or oxides of different or identical elements, and said elements are any elements capable to form a stable compound with the chalcogenide or with oxygen.

The specific conditions and the parameters involved in the synthesis of CdSe(core)/CdS(pods), CdSe(core)/CdSe(pods), CdSe(core)/CdTe(pods) octapods nanostructures are reported in the table 1 below.

TABLE 1

| | CdSe/CdS | CdSe/CdSe | CdSe/CdTe |
|---|---|---|---|
| Cu₂₋ₓSe/(mol) | 0.3*10⁻⁹ M | 0.3*10⁻⁹ M | 0.3*10⁻⁹ M |
| Precursor solution ^{a)} | S-TOP 0.5 g | Se-TOP 0.5 g | Te-TOP 0.1 g |
| T_{(injection)}/(° C.) | 320-380 | 300-350 | 280-320 |
| Grow time/(min) | 7 | 7 | 7 |

^{a)} Solution concentrations: S-TOP = 32 mg/ml, Se-TOP = 12 mg/ml, Te-TOP 10 wt %

### Structural and Morphological Characterization of the Octapod Nanocrystals

Structural and morphological characterization of the obtained structures was carried out via scanning electron microscopy (SEM), and transmission electron microscopy (TEM), by performing high resolution imaging (HRTEM), energy filtered imaging (EFTEM) and analytical scanning transmission imaging (EDS-STEM), to confirm the structures assessed by X-ray diffraction.

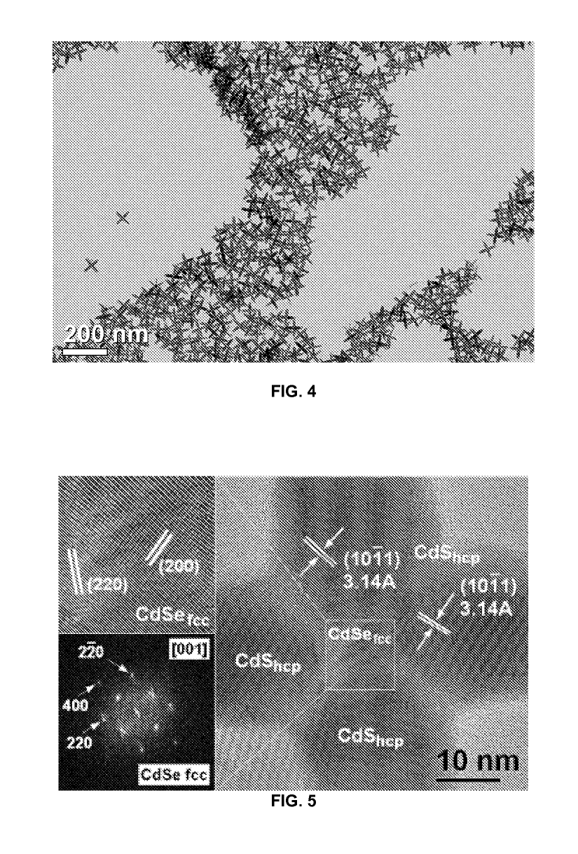

Morphological characterization was carried out by TEM and SEM. By analyzing a large number of octapods (several hundreds of nanoparticles), we were able to perform a statistical estimation of the average length and diameter of the pods in each octapod, which allowed us to conclude that the standard deviation in pod diameter is below 5% and the standard deviation in pod length is below 10%. In the analyzed samples, all octapods sitting on the substrate with four pods touching the substrate had a “Greek cross” shape in projection, since in this configuration the four pods touching the substrate are completely eclipsed by the four pods pointing upwards (FIG. 4).

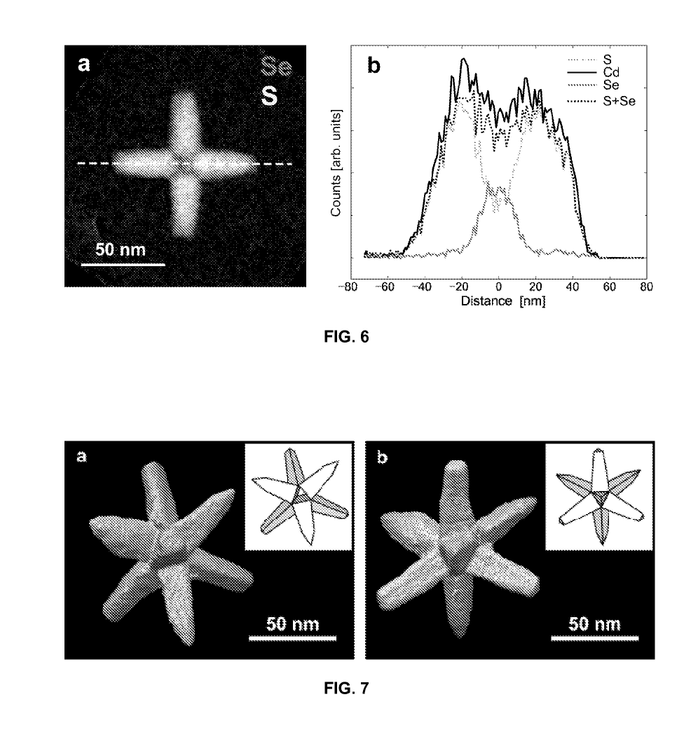

HRTEM reveals highly crystalline octapods (FIG. 5) preserving a cubic (sphalerite) core, with eight grown pods having wurtzite structure (hcp stacking). The pods are grown on the eight {111} facets of the unaltered seed. EFTEM imaging and energy dispersive spectroscopy (EDS-STEM) confirm the expected chemical composition of the core (made of CdSe) and of the pods (made of CdS) (FIG. 6).

Moreover, using different STEM projections of an octapod, the 3D shape is reconstructed, using tomographic reconstruction algorithms (FIG. 7). The resulting reconstruction reveals a peculiar symmetry. Due to the different growth rate of opposite directions ([0001] and [000 1̅]) of the hexagonal crystal structure forming the pods in the synthesis conditions, four pods (forming a structure with tetrahedral symmetry) have sharp tip ends, and the others flatter ends, reflecting a different behavior of the +{111} and −{111} seed faces. This shape is confirmed by SEM imaging of several octapods samples, even with different pod lengths.

### Optical Characterization

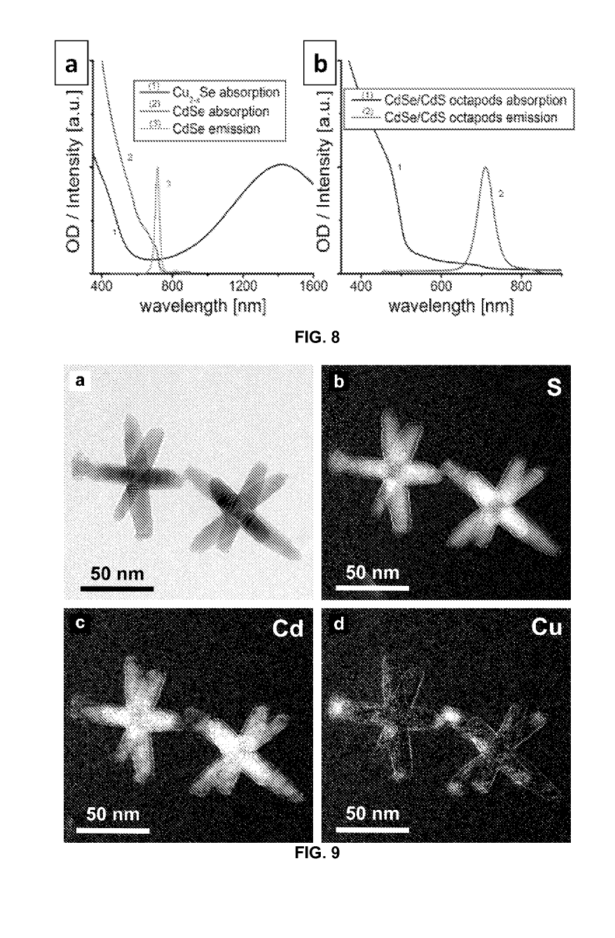

The optical characteristics of the octapods of the invention are illustrated with reference to the example nanocrystals: CdSe and CdSe(core)/CdS(pods). The optical extinction of the CdSe octapod nanocrystals shows a first excitonic transition which is close to the bulk band gap of CdSe (around 700 nm), since the particles are in this case large compared to the Bohr exciton radius in the bulk of this material. Accordingly also the band gap emission is similar to that of the bulk. The CdSe(core)/CdS(pods) octapods show a weak absorption around 700 nm which can be attributed to the CdSe core and a much stronger absorption around 480 nm which can be attributed to the CdS pods. The emission of this heterostructures is located at around 700 nm, which means that the radiative recombination of charge carriers occurs mainly in the core of the heterostructure. Overall, at least the steady state behavior of the CdSe(core)/CdS(pods) octapods is similar to that of the CdSe seeded CdS rods (FIG. 8).

### Porous Films of Disordered Octapod Nanocrystals

The present application also relates to the disordered aggregation of the above described octapod nanocrystals into a porous solid film. This film is made by simple deposition of a concentrated solution of octapods onto the surface of a substrate, followed by evaporation. Suitable substrates are any solid with a surface that can accommodate the film, preferably but not limited to a flat or close to flat surface, such as semiconductor wafer or glass slide or metal foil.

The film is prepared by depositing a concentrated solution of the octapods, obtained by dissolving nanocrystals in a non-polar or moderately polar solvent, for example toluene, chloroform. The concentration of octapods in this solution is at least 10⁻⁷ M.

The deposition may be performed by drop-casting, spraying or spin coating or doctor blading the concentrated solution, or yet dipping the substrate in the solution of octapods and retrieving it.

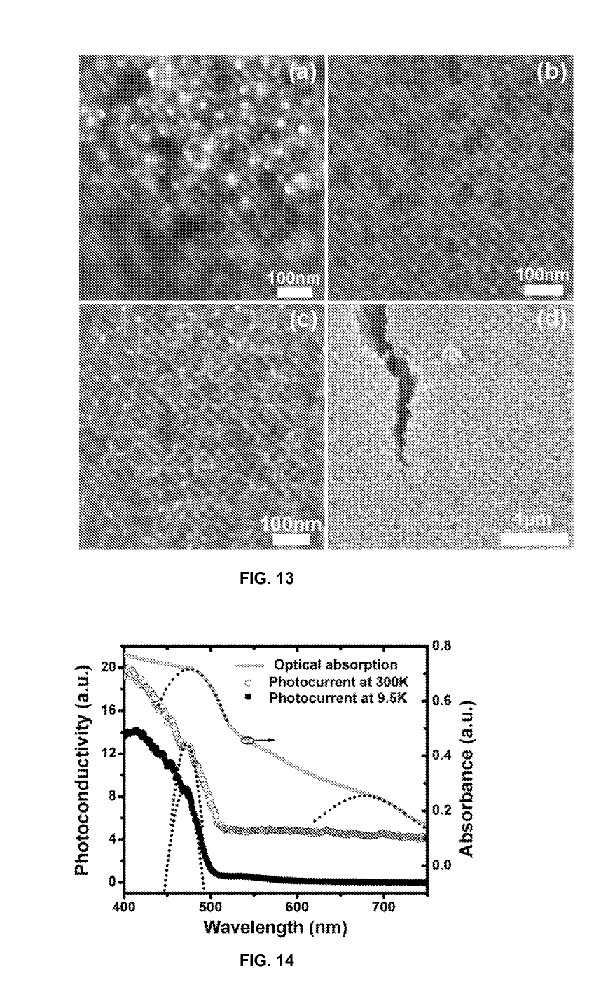

As-deposited films appeared blurry in SEM imaging (FIG. 13a) due to a significant amount of organic contaminants present in the film. These contaminants can be removed by an annealing process at temperature from 150° C. to 300° C., e.g. about 200° C. for a time from 5 min to 60 min, e.g. about 20 min. The annealing has to be performed under inert atmosphere, such as under nitrogen atmosphere. After annealing, the individual octapods and the porous structure of the octapod film can be clearly resolved in SEM images (FIG. 13b).

More dense packing of the octapods within the porous film can be achieved by immersion of the samples (substrates coated with porous octapod film) in a solution of a bifunctional linker, such as hydrazine, alkyldiamines, such as ethylendiamine, dithiols or any other usual linker. The crosslinking time ranges from 10 min to 2 days, e.g. for 1 hour. The reaction is stopped in ethanol and the film dried by nitrogen flow. The so-obtained film is then treated by a second thermal annealing process at the same condition described above. It is known that by such treatment the long chain surfactants that stabilize the nanocrystal surface are replaced by the much shorter hydrazine molecules, which reduces the inter particle distance and should significantly increase the film conductivity.

In an embodiment of the invention, the pores of the so obtained film may be filled with different materials capable of modulating the film properties. These materials can be polymers, or small molecules, or yet small nanoparticles that fit into the pores of the film. Filling can be realized by dipping, spraying, co-deposition, evaporation. Filling, if performed, may be carried out either before or after the above described crosslinking step.

In a further embodiment of the invention, the chemical characteristics of the so obtained films, either as such or crosslinked or filled with other materials or crosslinked and filled, are modified by a cation exchange reaction or by oxygen plasma treatment.

The cation exchange reaction is carried out at the same operative condition described above.

The oxidation treatment is performed by placing the films, deposited on the solid support, in an oxygen plasma at suitable conditions. for instance 3 min, with O₂ flow rate of 40 sccm and RF power of 25 W (13.56 MHz).

Following this procedure, the octapods in the film are “welded” together (see FIG. 15e). One interesting aspect of this welding procedure is that it produces a monolithic structure. The welding therefore improves the mechanical stability of the film, and thus improves charge conduction through it.

### Optical Characterization of Porous Octapod Films.

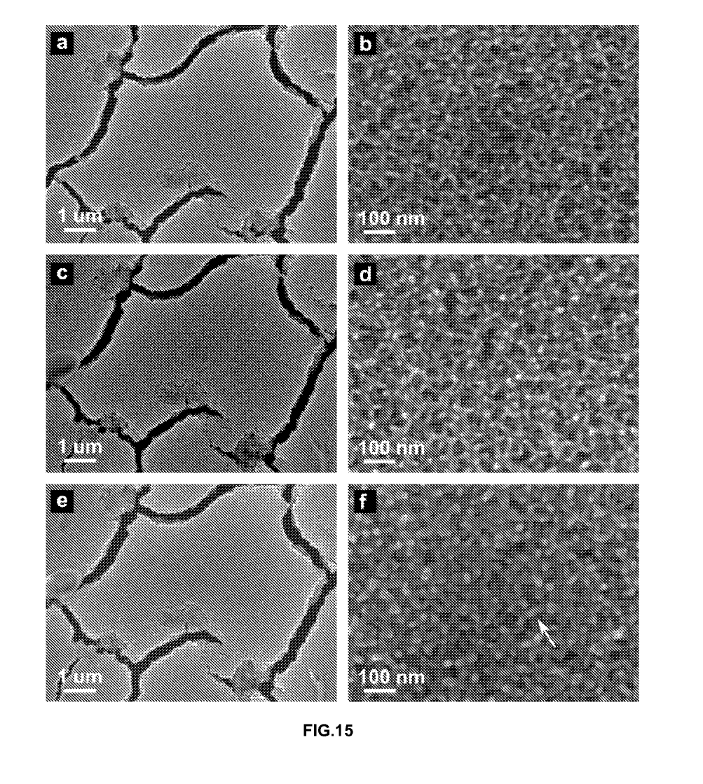

The optical absorption and the photocurrent of porous octapod films recorded versus the excitation wavelength (FIG. 14) exhibit a strong onset at 485 nm, which in both cases corresponds to the absorption from the CdS pods. The weak onset in the absorption spectrum around 700 nm correlates with the band gap of the CdSe cores. The gradual decrease of the absorption spectrum between 500 nm and 700 nm can be attributed to Rayleigh scattering of the incident light on micron size grains in the octapod film.

### Photo-Electrical Characterization of Porous Octapod Films.

Interdigitated electrodes were prepared using optical lithography that resulted in 8 μm spaced electrodes on planar glass substrates with thickness 5/50 nm of Ti/Au. The porous octapod films were prepared as described above. Photocurrent spectra were taken via illumination with a Xe white light source coupled to a monochromator (Spectral Physics CM110). FIG. 13 reports the photocurrent spectra at cryogenic and room temperatures plotted together with the absorption spectrum of the octapod film at room temperature.

### Applications

The octapod shaped nanocrystals can be used for preparing devices, which find many technical applications. Generally speaking, the octapod-shaped nanocrystals can be applied in photovoltaics and as building blocks in assemblies, to yield mesoporous materials of controlled porosity that can be applied in catalysis, in ion sensors, as active materials in energy storage applications and as hosts for other molecules and/or nanoparticles, for applications related to drug delivery, and decontamination of waters. Also, if individual octapods or groupings of them are contacted to various electrodes, they can be used as active elements in nanoscale electronic devices. When the octapod shaped nanocrystals are used in the form of a deposited film, then the film may be anyone of those described above. Specific examples of applications are disclosed hereinafter.

### Application of Octapods in Photovoltaics.

Films obtained by disordered aggregated octapod-shaped nanocrystals are used in hybrid organic-inorganic photovoltaic cells. More specifically, the void structures in these films are filled with a material (for example molecules/polymers or small nanocrystals) that behaves as good acceptors/conductor for one type of carrier (i.e. electron or hole), while the octapod film is a good acceptors/conductor for the opposite type of carrier. For this, an appropriate alignment of electronic levels of the octapod film and of the material used as “filler” must be realized. In one embodiment of the invention, this film is realized by preparing an “ink” made of CdS octapods and small CdTe nanoparticles dispersed in a suitable solvent, for example toluene, chloroform or trichloroethane. The choice of these materials is suggested by the fact that the respective band alignments are such that after generation electrons are transferred to the CdS octapods, while the holes are extracted to the CdTe nanocrystals. The film can be prepared by casting or spin coating or doctor blading a solution containing the CdS octapods and the CdTe nanocrystals on a suitable substrate, or yet dipping the substrate in the solution of octapods and retrieving it, and then allowing the solvent to evaporate. Various approaches, known from previous art, can be followed to facilitate electronic coupling between the two materials, for example via exchange of the surfactant coating the two types of nanoparticles with shorter molecules, such as pyridine, hydrazine or dithiols, optionally followed by thermal annealing. Some of these approaches are pre-deposition approaches (for example exchange with pyridine), while others can be post deposition (for example annealing).

This film can be viewed as two interpenetrated percolating networks of CdS octapods and CdTe nanoparticles. While a similar film can be prepared using other branched nanoparticles, for example tetrapods or urchin-like nanoparticles, the use of octapods in conjunction with nearly spherical nanoparticles of suitable sizes or combination of sizes allows to prepare a relatively uniform and compact film with reduction of porosity of the film. The formation of two interpenetrated percolating types of networks guarantees the formation of a large interfacial area between the two materials, which increases the rate of charge separation, and increases the probability for photogenerated carriers of opposite charges to reach the anode and cathode, respectively, i.e. it increases the charge transport and charge collection rates.

In another embodiment of the invention, the film can be made of a mixture of octapods of a suitable semiconductor material (or a combination of semiconductor materials) and an organic component, for example a molecule/polymer that behaves as good hole acceptor and conductor (for example P3HT), or alternatively a molecule/polymer that behaves as a good electron acceptor/conductor (for example C60 or one of its modifications) if in this combination the octapods behave as good hole acceptor/conductor. Then depending on the relative band alignments, carriers of a given sign will travel preferentially either in the nanocrystal or in the organic percolating network inside the film.

The resulting film can then be sandwiched between electrodes, of which one is transparent to solar light, therefore realizing a solar cell. Upon absorption of light, electron-hole pairs are created inside the cell. The pairs separate at the nanocrystal-nanocrystal interface or organic-nanocrystal interface (depending on the type of film), with electrons staying in one type of percolating network and the holes staying in the other percolating network. Both carriers are able to travel to the respective electrodes.

### Application of Octapod in Li⁺ Ion Batteries.

In another embodiment of the invention, films of octapod-shaped nanocrystals are used as electrodes in Li⁺ ion batteries. As one example, it is possible to fabricate very light weight, porous conducting carbon substrates. Films of octapods are fabricated of the relevant electrode materials capable of being lithiated and de-lithiated reversibly, and the voids in the films can be filled with highly electrically conductive carbon material. The overall structure has the advantage of expected relatively high mechanical stability combined with a light weight and high porosity. In addition, ionic and electronic conducting pathways exist in an octapod film, which means that some unwanted loss of contact can be circumvented easily, unlike in a 1D wire. Porous films of conductive octapod are also used as porous electrodes in batteries, while the voids in the films could be filled with a material able to undergo reversible lithiation/de-lithiation.

### Application of Octapod Films in Ion Sensing.

In another embodiment, films of octapod-shaped nanocrystals are also used in ion sensing applications. As one example, a film of octapods in electrical contact between a source and a drain electrode, would exhibit a given charge conductivity behavior, related to the type of material of which the octapod are made. Upon exposing this device to a solution of cations capable of exchanging the cations of the octapod superstructure, a change in conductivity would be registered, which can be correlated to the type and concentration of ionic species in solution. The sensing response could be fast, due to the porous structure of the network, and could also be reversible, due to the reversibility of the cation exchange reactions.

### Application of Octapod Films in Red-Ox Reactions, as Reservoirs of Chemicals, as Drug Delivery Agents.

In another embodiment, films of octapod-shaped nanocrystals are also used in a wide variety of applications, ranging from redox-reactions and accumulation of chemicals to delivery of drugs/molecules. This is possible thanks to their porous structure, and to the possibility to functionalize the surface of the octapods with moieties that can help to link various molecules, using known surface chemistry. Depending on the desired application, octapods can serve as porous host in which chemicals can continuously diffuse in and out and react when they are inside the film with other reagents, or they can remain trapped inside and can be released upon application of a well defined external stimulus. One example is represented by a porous film of metal oxide octapods entrapping at its interior small (1-2 nm large) noble metal nanoparticles (Au, Pd, Pt), each particle in electrical contact with the film. This combination of materials, at these size scales, is known to exhibit a high catalytic activity towards a series of important reactions, for example the water gas shift reaction and the selective carbon monoxide oxidation.

### Application of Octapod Films as Filter Membranes.

In another embodiment, mechanically stable octapod films are prepared, which can be used as filter membranes of controlled porosity. Disordered films of as-deposited octapods on a substrate can be made mechanically stable by a series of treatments, which include annealing at a temperature that removes the organic coating and promotes sintering of octapods, soaking into a solution of hydrazine or dithiols, which are bifunctional linkers that glue the octapods together, or yet by exposing the film to a mild oxygen plasma treatment.

The substrate can be made such that it can be dissolved/destroyed in a second step, without compromising the octapod film. For example, it can be a water soluble polymer substrate (capable of withstanding the above procedures of consolidation of the octapod film), or a KBr pellet, and in both cases a careful treatment of the sample with water can yield a free-standing octapod film (for example floating on the surface of water, from which it can be fished and transferred to another support). The substrate can also be a material that can be selective removed by a chemical etching step that does not affect the octapod film, for example an oxide material that can be removed by acid/basic etching. The obtained octapod films have a porosity that is dictated by the size of the octapods and their detailed geometrical parameters. Therefore, free-standing membranes obtained from films of disordered octapods welded together can be used as filter membranes, or as support for catalyst particles of specific sizes.

### EXAMPLES

### Example 1

### Synthesis of Berzelianite Cu₂₋ₓSe Nanocrystals

Anhydrous CuCl (0.099 g, 1 mmol) was first added to a mixture of 5 ml of oleylamine and 5 ml of 1-octadecene (ODE) in a reaction flask. After pumping to vacuum for 1 hour at 80° C. using a standard Schlenk line, the reaction mixture was put under constant nitrogen flow. The temperature was then set to 300° C. A solution of Se in oleylamine was freshly prepared by mixing 0.039 g of Se (0.5 mmol) with 3 ml of oleylamine. The solution was heated to 150° C. under vacuum using a standard Schlenk line for 1 hour and later the line was switched to nitrogen flow and the temperature was raised to 230° C. and kept there for 1 hour in order to fully dissolve Selenium. This mixture was then cooled down to 100° C. The solution was kept at this temperature and transferred into a glass syringe equipped with a large needle (12 gauge external diameter) and injected quickly into the flask. After injection, the temperature of the reaction mixture dropped to 280° C., and it was allowed to recover to the pre-injection value. The overall reaction time after injection was 15 min, after which the flask was rapidly cooled to room temperature. Once at room temperature, 5 ml of toluene was added to the reaction mixture, and the resulting solution was transferred into a vial under nitrogen flow, and the vial was then stored inside a glove box. This solution was then washed by repeated precipitations (via addition of ethanol) and re-dissolution in toluene. After the last washing step, the Cu₂₋ₓSe nanocrystals were dissolved in 3 ml of toluene.

### Example 2

### Synthesis of Octapods by In Situ Cation Exchange and Seeded Growth (“One Pot Procedure”)

The synthesis of the octapods was carried out via a seeded growth approach. A solution was prepared inside the glove box, which contained S dissolved in TOP (see table 1 for details) and previously synthesized Cu₂₋ₓSe seeds, the latter in a known concentration (see table 1). This solution was injected into a reaction flask containing a mixture of surfactants (3 g TOPO, 80 mg HPA, 290 mg ODPA) and 60 mg of CdO heated at a specified temperature under nitrogen atmosphere. After the injection, the resulting solution was allowed to recover at the pre-injection temperature for 7 min, after which it was cooled to room temperature (see table 1 for details). This solution was then washed by repeated precipitations (via addition of methanol) and re-dissolution in toluene. After the last washing step, the octapods were dissolved in 5 ml of toluene. The as-synthesized octapods were stored under nitrogen inside a glove box.

### Example 3

### Synthesis of Octapods by a Two-Step Reaction (Two Pot Procedure): 1. Cation Exchange, 2. Seeded Growth

3.1. Synthesis of Cubic CdSe Nanocrystals (Diameter Larger than 5 nm) Via Ion Exchange of Berzelianite Cu₂₋ₓSe Nanocrystals

Cu₂₋ₓSe nanocrystals in TOP were injected into a reaction flask which contained a mixture of cadmium alkylphosphonates (HPA and ODPA) in trioctylphosphine oxide (TOPO) heated to 350° C. (without TOP-S) and the resulting solution was kept under these conditions for 1 min to 7 min (Several test reactions were carried out and the results suggest that the cation exchange reaction is complete after 1 min and a longer reaction time does not significantly influence the final product). The solution was washed by repeated precipitations (via addition of ethanol) and re-dissolved in toluene. After the last washing step, the particles were dissolved in 2 ml of TOP. The obtained 15-20 nm nanocrystals were relatively uniform and the sample had a narrow particle size distribution. Furthermore, XRD analysis confirmed that the final product was sphalerite CdSe.

### 3.2. Seeded Growth of Octapods:

Sphalerite CdSe nanocrystals, as obtained from cation exchange reaction described in the previous section, were dispersed in TOP and the concentration of the final solution was determined by building a structural model of the nanocrystal with the same geometrical parameters as determined by TEM and elemental analysis. For the “two-pot” synthesis the same amount of sphalerite CdSe seeds was used as of the Cu₂₋ₓSe seeds in case of the “one-pot” synthesis (0.3*10⁻⁹ moles of nanocrystals). The as prepared seeds were mixed with TOP-S (same amount like in the reaction with Cu₂₋ₓSe seeds). The mixture was injected into the reaction flask containing a mixture of surfactants (3 g TOPO, 80 mg HPA, 290 mg ODPA) and 60 mg of CdO as in the case of the one-pot synthesis described previously in the report. As a result uniform octapods were obtained.

### Example 4

### Cation Exchange Reactions of the CdSe/CdS Octapods

Cu⁺ ion exchange was performed in an argon-filled glove box. In a standard procedure, a stock solution of Cu⁺ ion precursor was prepared by dissolving 10 mg of Cu precursor (Tetrakisacetonitrilcopper(I)hexafluorophosphate) in 5 ml of methanol. Reaction vials were prepared containing 5 ml of methanol and 0.5 ml of toluene. Subsequently, fixed amounts (see table 2) of copper (I) precursor were added into the vials with methanol and toluene. In the last step, 50 μL of octapod solution in toluene were injected into each of these vials (the concentration of the octapod-shaped particles in the solution was 1.2×10⁻⁷ M with a Cd²⁺ ions concentration equal to 2.17×10⁻² M). When a lower amount of copper(I) precursor was used, the final color of the solution was dark yellow, while in the vials with higher amount of Cu⁺ ions added the color of the solution changed rapidly from yellow to brown. Finally, the as prepared sample was precipitated and redissolved in chloroform. Syntheses numbered 1, 2 and 3 yielded ternary octapod compounds while 4 and 5 caused full Cd²⁺ exchange in the original octapods leading to Cu₂₋ₓSe(core)/Cu₂S (pods) compound.

TABLE 2
Amounts of precursor used for the cation exchange reaction. The concentration
of Cu⁺ ions in the stock solution is 5.3 × 10⁻³ M.

| | Amount of Cu precursor in the sample | | | |
|---|---|---|---|---|
| Sample | taken form the stock solution−> | | | Amount of octapods solution −> |
| number | number of moles of Cu⁺ ions added | Methanol | Toluene | molar number of Cd²⁺ |
| 1 | 50 uL−> 2.68 × 10⁻⁷ mol | 5 ml | 0.5 ml | 50 uL−> 1.08 × 10⁻⁶ mol |
| 2 | 100 uL−>5.3 × 10⁻⁷ mol | 5 ml | 0.5 ml | 50 uL−> 1.08 × 10⁻⁶ mol |
| 3 | 250 uL−>1.3 × 10⁻⁶ mol | 5 ml | 0.5 ml | 50 uL−> 1.08 × 10⁻⁶ mol |
| 4 | 500 uL (excess)−>2.68 × 10⁻⁶ mol | 5 ml | 0.5 ml | 50 uL−> 1.08 × 10⁻⁶ mol |
| 5 | 2000 uL (excess)−>10.72 × 10⁻⁶ mol | 5 ml | 0.5 ml | 50 uL−> 1.08 × 10⁻⁶ mol |

### Example 5

### Deposition of a Disordered Film of Octapods

A porous disordered solid film of octapods is prepared by simple deposition of a concentrated solution (10⁻⁷ M or higher) of octapods on a substrate, for example by drop-casting or spin-coating or spray painting or doctor blading, or yet dipping the substrate in the solution of octapods and retrieving it, followed by evaporation of the solvent. As-deposited films appeared blurry in SEM imaging (FIG. 13a), due to the presence of organic contaminants in the film. These contaminants can be removed by an annealing process at 200° C. for 20 min, which is performed preferably under inert atmosphere. After annealing, the individual octapods and the porous structure of the octapod film can be clearly resolved in SEM images (FIG. 13b). More dense packing of the octapods within the porous film can be achieved by immersion of the samples (substrates coated with the porous octapod film) in hydrazine solution (2M concentration in ethanol) for 1 hour (stopped in ethanol and dried by nitrogen flow), followed by the same thermal annealing process as described above. It is known that by such treatment the long chain surfactants that stabilize the nanocrystal surface are replaced by the much shorter hydrazine molecules, which reduces the inter particle distance and should significantly increase the film conductivity. Typical thicknesses of the disordered porous octapod films that were fabricated by drop-casting concentrated octapod solution onto SiO₂ substrates are around 100 to 200 nm.

### Example 6

### Direct Cation Exchange on CdSe/CdS Octapods Films

The detailed experimental description of the procedure is as follows: a film of CdSe/CdS octapods, deposited on a silicon substrate, is dipped in a solution of 37 mg Cu(CH₃CN)₄PF₆ in 5 mL of methanol for at least 15 min. Afterwards, the substrate with the cation exchanged substrate is dipped into 5 mL of pure methanol for 15 min to wash away excessive Cu(CH₃CN)₄PF₆ and released Cd compounds. This cleaning step is repeated a second time with another 5 mL pure methanol. Afterwards the sample is allowed to dry for several hours.

### Example 7

### Oxygen Plasma Treatment of the Cu₂Se/Cu₂S Octapod Film

The films of Cu₂Se/Cu₂S octapods which are deposited on a substrate are placed in a Gatan Advanced Plasma System (model Solarus 950). The plasma (oxygen plasma) is applied for at least 3 min at an O₂ flow rate of 40 sccm and a RF power of 25 W (13.56 MHz). Following this procedure, the octapods in the film are “welded” together (see FIG. 15). One interesting aspect of this welding procedure is that it produces a monolithic structure. The welding is therefore expected to improve the mechanical stability of the film, and to improve charge conduction through it.

### REFERENCES

1. Alivisatos, A. P., X. G. Peng, and L. Manna, U.S. Pat. No. 6,225,198: Process for forming shaped group II-VI semiconductor nanocrystals, and product formed using process’. 2001.
2. Alivisatos, A. P., E. C. Scher, and L. Manna, U.S. Pat. No. 6,855,202: Shaped nanocrystal particles and methods for making the same. 2005.
3. Alivisatos, A. P., E. C. Scher, and L. Manna, U.S. Pat. No. 7,311,774: ‘Shaped nanocrystal particles and methods for working the same’. 2007.
4. Alivisatos, A. P., et al., U.S. Pat. No. 7,303,628: ‘Nanocrystals with linear and branched topology’. 2007.
5. Carbone, L., et al., Synthesis and micrometer-scale assembly of colloidal CdSe/CdS nanorods prepared by a seeded growth approach. Nano Letters, 2007. 7 (10): p. 2942-2950.
6. Fiore, A., et al., Tetrapod-Shaped Colloidal Nanocrystals of II-VI Semiconductors Prepared by Seeded Growth. Journal Of The American Chemical Society, 2009. 131 (6): p. 2274-2282.
7. Kanaras, A. G., et al., Controlled synthesis of hyperbranched inorganic nanocrystals with rich three-dimensional structures. Nano Letters, 2005. 5 (11): p. 2164-2167.
8. Gou, L. F. and C. J. Murphy, Fine-tuning the shape of gold nanorods. Chemistry Of Materials, 2005. 17 (14): p. 3668-3672
9. Habas, S. E., et al., Shaping binary metal nanocrystals through epitaxial seeded growth. Nature Materials, 2007. 6 (9): p. 692-697.
10. He, X. B. and L. Gao, Morphology and Phase Evolution of Hierarchical Architectures of Cadmium Sulfide. Journal Of Physical Chemistry C, 2009. 113 (25): p. 10981-10989.
11. Cao, X. B., et al., Rapid phosphine free growth of diverse CdSe multipods via microwave irradiation route. Journal Of Alloys And Compounds, 2009. 474 (1-2): p. 61-67.
12. Bashouti, M. and E. Lifshitz, PbS sub-micrometer structures with anisotropic shape: Ribbons, wires, octapods, and hollowed cubes. Inorganic Chemistry, 2008. 47 (2): p. 678-682.
13. Wang, X. Q., et al., Controllable synthesis of PbSe nanostructures and growth mechanisms. Crystal Growth & Design, 2008. 8 (4): p. 1406-1411.
14. Ren, J. T. and R. D. Tilley, Preparation, self-assembly, and mechanistic study of highly monodispersed nanocubes. Journal of the American Chemical Society, 2007. 129 (11): p. 3287-3291.
15. Cheong, S., et al., In Situ and Ex Situ Studies of Platinum Nanocrystals: Growth and Evolution in Solution. Journal Of The American Chemical Society, 2009. 131 (40): p. 14590-14595.
16. Chou, S. W., et al., Controlled Growth and Magnetic Property of FePt Nanostructure: Cuboctahedron, Octapod, Truncated Cube, and Cube. Chemistry Of Materials, 2009. 21 (20): p. 4955-4961.
17. Chang, Y. and H. C. Zeng, Manipulative synthesis of multipod frameworks for self-organization and self-amplification of Cu2O microcrystals. Crystal Growth & Design, 2004. 4 (2): p. 273-278.
18. Jain, P. K., et al., Nanoheterostructure Cation Exchange: Anionic Framework Conservation. Journal of the American Chemical Society, 2010, 132 (29), 9997-9999.
19. Lambert, K., et al., PbTelCdTe CorelShell Particles by Cation Exchange, a HR-TEM study. Chemistry Of Materials, 2009. 21 (5): p. 778-780.
20. Houtepen, A. J., R. Koole, D. I. Vanmaekelbergh, J. Meeldijk, and S. G. Hickey, The Hidden Role of Acetate in the PbSe Nanocrystal Synthesis. Journal of the American Chemical Society, 2006. 128 (21): p. 6792.
21. Deka, S., A. Genovese, Z. Yang, K. Miszta, G. Bertoni, R. Krahne, C. Giannini, and L. Manna, Phosphine-Free Synthesis of p-Type Copper(I) Selenide Nanocrystals in Hot Coordinating Solvents. Journal of the American Chemical Society, 2010. 132 (26): p. 8912-8914.
22. He, P., X. Shen, and H. Gao, Size-controlled preparation of Cu2O octahedron nanocrystals and studies on their optical absorption. Journal of Colloid and Interface Science, 2005. 284 (2): p. 510.
23. Shanmugam, S, and A. Gedanken, MnO Octahedral Nanocrystals and MnO@C Core-Shell Composites: Synthesis, Characterization, and Electrocatalytic Properties. The Journal of Physical Chemistry B, 2006. 110 (48): p. 24486.
24. Shengyu, J. and et al., Synthesis and characterization of octahedral PbS nanocrystals assisted with mixed cationic/anionic surfactants. Journal of Physics: Conference Series. 276 (1): p. 012211.
25. Tao, F., Z. Wang, L. Yao, W. Cai, and X. Li, Shape-Controlled Synthesis and Characterization of YF3 Truncated Octahedral Nanocrystals. Crystal Growth & Design, 2007. 7 (5): p. 854
26. Lu, W., Q. Liu, Z. Sun, J. He, C. Ezeolu, and J. Fang, Super Crystal Structures of Octahedral c-In2O3 Nanocrystals. Journal of the American Chemical Society, 2008. 130 (22): p. 6983.

1. A process for preparing colloidal octapod-shaped nanocrystal comprising the following steps:
providing nanocrystal seeds of a material crystallized in a cubic phase, having eight developed {111} facets and being larger than 5 nanometers,
contacting the nanocrystal seeds with one or more precursors to cause the seeded growth of the pods of a material crystallizing in an hexagonal phase on the eight {111} facets,
obtaining the octapod-shaped nanocrystals,
wherein the nanocrystal seeds and the growth precursor comprise the same or different materials.

2. The process according to claim 1, wherein the nanocrystal seeds comprise a material selected from:
A group IV semiconductor, a group III-V semiconductor, a IV-VI semiconductor, a II-VI semiconductor, a single-element material, a multi-metallic material, an oxide of one or more elements, or one material not comprised in the above groups and being selected from Cu₂Se, Cu₂₋ₓSe, Cu₂₋ₓSe_{1-y}S_{y}, Cu₂S, Cu_{2.86}Te, Ag₂Se, AgSe, Ag₂S, Ag₂Te, CoSe, CoSe₂, CoS₂, CoTe₂, Co₃Se₄, Co₉S₈, ZnSO₄, SeS, MnSe, MnSe₂, MnS, MnSe₂, MnTe₂, MnS_{1-y}Se_{y}, MnSe_{1-y}Te_{y}, SiC (3C), SiGe, CuIn₁₋ₓGaₓSe₂, Zn₃As₂, Li₃NbO₄, La₂CuO₄, Ga₄Se₈, Ga_{1.33}Se₂, MnₓIn₁₋ₓAS, CdₓMn₁₋ₓTe, Mn_{0.4}Pb_{3.6}Te₄, CuInₓGa₁₋ₓSe₂, CuInSe₂, Ag_{0.2}Ga_{2.56}S₄, YF₃.

3. The process according to claim 2, wherein the nanocrystal seeds consist of CdSe in the cubic sphalerite phase having octahedral, cuboctahedral or truncated octahedral shape.

4. The process according to claim 1, wherein the growth precursors for the pods are chemical species generating one of the following material: a group IV semiconductor crystallizing in an hexagonal phase, a group III-V semiconductor crystallizing in an hexagonal phase, a IV-VI semiconductor crystallizing in an hexagonal phase, a II-VI semiconductor crystallizing in an hexagonal phase, a single element material crystallizing in an hexagonal phase, an oxide of one or more elements crystallizing in an hexagonal phase, or one material not comprised in the above groups and being selected from Cu₂S, Cu₂₋ₓS, CuSe, Cu₂Te, Cu₂₋ₓSe_{1-y}S_{y}, Cu₂ZnSnS₄, CuS, Se, Co, CoSe, CoTe, CoS, Ag₂Se, MnS MnTe, MnSe, MnTe_{1-y}Se_{y, SiC (}4H, 6H), Sb, AsSb, SbN₉, Zn_{3.83}Sb₃, Bi₂Te₃, CdSb, LiNbO₂, LiNbO₂, PbI₂ MoSe₂, As_{0.5}Ga_{0.5}Mn₂, AsMn, Ag_{0.144}Ga_{1.286}S₂, Pt₂Si₃, Pt₂Si.

5. The process according to claim 1, wherein the material of the nanocrystal seeds and the material of the pods are chalcogenides or oxides of different or identical elements, and said elements are any elements capable to form a stable compound with the chalcogenide or with oxygen.

6. The process of claim 1, wherein the pods have hexagonal wurtzite crystal phase.

7. The process of anyone of claim 1, which further comprises the subjecting of the obtained octapod-shaped nanocrystals to a step of cation exchange and/or a step of oxidation.

8. The process of claim 1, wherein the nanocrystal seeds are prepared by:
subjecting a first nanocrystal comprising cations of a first element and having eight {111} facets to cation exchange reaction with cations of a second different element;
obtaining said nanocrystal seeds comprising the cation of said second element,
wherein said first nanocrystals comprise a material selected from: a group IV semiconductor crystallized in a cubic phase, a group III-V semiconductor crystallized in a cubic phase, a IV-VI semiconductor crystallized in a cubic phase, a II-VI semiconductor crystallized in a cubic phase, an oxide of one or more elements crystallized in a cubic phase, or one material not comprised in the above groups and being selected from Cu₂Se, Cu₂₋ₓSe, Cu₂₋ₓSe_{1-y}S_{y}, Cu₂S, Cu_{2.86}Te, Ag₂Se, AgSe, Ag₂S, Ag₂Te, CoSe, CoSe₂, CoS₂, CoTe₂, Co₃Se₄, Co₉S₈, ZnSO₄, SeS, MnSe, MnSe₂, MnS, MnSe₂, MnTe, MnS_{1-y}Se_{y}, MnSe_{1-y}Te_{y}, SiC (3C), SiGe, CuIn₁₋ₓGaₓSe₂, Zn₃As₂, Li₃NbO₄, La₂CuO₄, Ga₄Se₅, Ga_{1.33}Se₂, MnₓIn₁₋ₓAS, CdₓMn₁₋ₓTe, Mn_{0.4}Pb_{3.6}Te₄, CuInₓGa₁₋ₓSe₂, CuInSe₂, Ag_{0.28}Ga_{2.56}S₄, YF₃₄.

9. The process of claim 8, wherein the first nanocrystals are monodisperse Cu₂₋ₓSe nanocrystals in the cubic berzelianite phase having cuboctahedral shape.

10. The process of claim 8, wherein the cation of the second element derives from a material selected from: A group IV semiconductor, a group III-V semiconductor, a IV-VI semiconductor, a II-VI semiconductor, an oxide of one or more elements, or one material not comprised in the above groups and being selected from Cu₂Se, Cu₂₋ₓSe, Cu₂₋ₓSe_{1-y}S_{y}, Cu₂S, Cu_{2.86}Te, Ag₂Se, AgSe, Ag₂S, Ag₂Te, CoSe, CoSe₂, CoS₂, CoTe₂, Co₃Se₄, Co₉S₈, ZnSO₄, SeS, MnSe, MnSe₂, MnS, MnSe₂, MnTe₂, MnS_{1-y}Se_{y}, MnSe_{1-y}Te_{y}, SiC (3C), SiGe, CuIn₁₋ₓGaₓSe₂, Zn₃As₂, Li₃NbO₄, La₂CuO₄, Ga₄Se₈, Ga_{1.33}Se₂, MnₓIn₁₋ₓAs, CdₓMn₁₋ₓTe, Mn_{0.4}Pb_{3.6}Te₄, CuInₓGa₁₋ₓSe₂, CuInSe₂, Ag_{0.28}Ga_{2.56}S₄, YF₃.

11. The process of claim 1, wherein the step of providing the nanocrystal seeds and the step of growing the pods is carried out in one step.

12. The process of claim 1, wherein the steps of providing the seeds and growing the pods are carried out in presence of a mixture of surfactants and organic solvents selected from the group consisting of alkylphosphines, alkylphosphine-oxides, alkylphosphonic acids, alkylamines, fatty carboxylic acids or fatty alkanes, fatty alkenes, aromatic compounds and ethers or mixture thereof.

13. Colloidal octapod-shaped nanocrystals obtained by the process of claim 1, having a core and eight pods, having non-octapod particle fraction less than 5% and standard deviation of pods length below 10%.

14. The colloidal octapod-shaped nanocrystals of claim 13, wherein the cores comprise a material crystallized in a cubic phase selected from a group IV semiconductor, a group III-V semiconductor, a IV-VI semiconductor, a II-VI semiconductor, a single-element material, a multi-metallic material, an oxide of one or more elements, or one material not comprised in the above groups and being selected from Cu₂Se, Cu₂₋ₓSe, Cu₂₋ₓSe_{1-y}S_{y}, Cu₂S, Cu_{2.86}Te, Ag₂Se, AgSe, Ag₂S, Ag₂Te, CoSe, CoSe₂, CoS₂, CoTe₂, Co₃Se₄, Co₉S₈, ZnSO₄, SeS, MnSe, MnSe₂, MnS, MnSe₂, MnTe₂, MnS_{1-y}Se_{y}, MnSe_{1-y}Te_{y}, SiC (3C), SiGe, CuIn₁₋ₓGaₓSe₂, Zn₃As₂, Li₃NbO₄, La₂CuO₄, Ga₄Se₈, Ga_{1.33}Se₂, MnₓIn₁₋ₓAS, CdₓMn₁₋ₓTe, Mn_{0.4}Pb_{3.6}Te₄, CuInₓGa₁₋ₓSe₂, CuInSe₂, Ag_{0.28}Ga_{2.56}S₄, YF₃;
and the pods comprise a material crystallized in an hexagonal phase selected from: a group IV semiconductor, a group III-V semiconductor, a IV-VI semiconductor, a II-VI semiconductor, a single element material, a multi-metallic material, an oxide of one or more elements, or one material not comprised in the above groups and being selected from Cu₂S, Cu₂₋ₓS, CuSe, Cu₂Te, Cu₂₋ₓSe_{1-y}S_{y}, Cu₂ZnSnS₄, CuS, Se, Co, CoSe, CoTe, CoS, Ag₂Se, MnS MnTe, MnSe, MnTe_{1-y}Se_{y}, SiC (4H, 6H), Sb, AsSb, SbN₉, Zn_{3.93}Sb₃, Bi₂Te₃, CdSb, LiNbO₂, LiNbO₂, PbI₂ MoSe₂, As_{0.5}Ga_{0.5}Mn₂, AsMn, Ag_{0.144}Ga_{1.286}S₂, Pt₂Si₃, Pt₂Si.

15. The colloidal octapod-shaped nanocrystals of claim 13, wherein the core and the pods are chalcogenides or oxides of different or identical elements, and said elements are any elements capable to form a stable compound with the chalcogenide or with oxygen.

16. The colloidal octapod-shaped nanocrystals of claim 15, wherein the core consists of CdSe, Cu₂Se, Cu₂₋ₓSe, Cu₂₋ₓSe_{1-y}S_{y}, CdSe_{1-y}S_{y}, CuSe, Ag₂Se, CoSe, ZnSe, MnSe, ZnO, MnO, CoSe, CoO, or mixture thereof and the pods consist of CdSe, Cu₂S, Cu₂₋ₓS, CdSe_{1-y}S_{y}, Cu₂₋ₓSe_{1-y}S_{y}, CuS, Ag₂Se, Ag₂O, Ag₂S, PbSe, CdSe, PbS, ZnS, MnS, CoS, or mixture thereof.

17. The colloidal octapod-shaped nanocrystals of claim 13 consisting of CdSe(core)/CdS(pods), CdSe(core)/CdSe(pods), CdSe(core)/CdTe(pods), Cu₂Se(core)/Cu₂S(pods), Cu₂₋ₓSe(core)/Cu₂₋ₓS(pods), CuSe(core)/CuS(pods), Ag₂Se(core)/Ag₂S(pods), PbSe(core)/PbS(pods), ZnSe(core)/ZnS(pods), MnSe(core)/MnS(pods), CoSe(core)/CoS(pods), CdSe(core)/[CdS+Cu₂S](pods), CdSe(core)/[CdS+Ag₂S](pods).

18. The colloidal octapod-shaped nanocrystals of claim 17, wherein the core consists of CdSe, in the cubic sphalerite phase and the pods consist of CdS or CdSe in hexagonal wurtzite phase.

19. The octapod-shaped nanocrystals of claim 14, when aggregated in disordered way in a porous film on a substrate.

20. The aggregated octapod-shaped nanocrystals of claim 19, where the pores of the octapod film are filled with a different material.

21. The aggregated octapod-shaped nanocrystals of claim 19, modified by cation exchange or oxygen plasma treatments.

22. A process for the preparation of the film of disordered octapod-shaped nanocrystals of claim 19 comprising the steps of:
i) preparing a concentrated solution at least 10⁻⁷ M of the octapods;
ii) drop-casting or spin coating or spray painting or doctor blading the concentrated solution of octapods onto a substrate, or dipping the substrate in the solution of octapods and retrieving it;
iii) evaporating the solvent;
iv) performing an annealing process at temperatures comprised between 150° C. and 300° C. for a time period between 5 and 60 min, preferably under inert atmosphere.

23. The process of claim 22, further comprising the steps of:
v) causing a more dense packing of the octapods within the porous film, by immersing the sample in a solution of a bifunctional linker for a time ranging from 10 min to 2 days,
vi) repeating the annealing treatment as in point iv).

24. The process of claim 23, wherein the bifunctional linker is selected from the group comprising a diamine, a hydrazine, a dithiol, a dicarboxylic acid, a diphosphonic acid.

25. The process of claim 22, where the pores of the octapod film are filled with a different material.

26. The process of claim 22, further comprising the step of subjecting the nanocrystal film deposited on a solid substrate to cation exchange reaction and/or to oxygen plasma treatment.

27. The process of claim 23, further comprising the step of subjecting the nanocrystal film deposited on a solid substrate to cation exchange reaction and/or to oxygen plasma treatment.

28. A devices comprising the film of disordered octapod-shaped nanocrystals of claim 19, wherein said device is an element of a photonic crystal structure for deep-UV light, an element of a photovoltaic cell, an electrode in Li+ ion batteries, a support for plasmonic applications, an element of ion sensor, a support for redox reaction, a nanocontainer or a drug delivery agent.

29. A devices comprising the film of disordered octapod-shaped nanocrystals of claim 20, wherein said device is an element of a photonic crystal structure for deep-UV light, an element of a photovoltaic cell, an electrode in Li+ ion batteries, a support for plasmonic applications, an element of ion sensor, a support for redox reactions, a nanocontainer or a drug delivery agent.

30. The devices comprising the film of disordered octapod-shaped nanocrystals of claim 21, wherein said device is an element of a photonic crystal structure for deep-UV light, an element of a photovoltaic cell, an electrode in Li+ ion batteries, a support for plasmonic applications, an element of ion sensor, a support for redox reaction, a nanocontainer or drug delivery agents.

31. A process for the preparation of nanocrystals having eight developed {111} facets and diameter larger than 5 nanometers, comprising:
subjecting a first nanocrystal comprising a chalcogenide of a first element and having eight {111} facets to cation exchange reaction with cations of a second different element to obtain nanocrystal of said second element chalcogenides having eight developed {111} facets and diameter larger than 5 nm;
isolating the so obtained nanocrystal,
wherein, said cation of a second element is any cation which forms a stable solid compound with the chalcogenide.

32. The process of claim 31, wherein the nanocrystals of said first and second element have octahedral, cuboctahedral or truncated octahedral shape/habit.

33. The process of claim 32, wherein the first element chalcogenide is a sample of mono-dispersed Cu₂₋ₓSe nanocrystals in the cubic berzelianite phase having cuboctahedral shape or an alloy Cu₂₋ₓSe_{1-y}S_{y}.

34. The process of claim 31, wherein the cation exchange reaction comprises the step of:
mixing monodisperse Cu₂₋ₓSe nanocrystals phase in a solution of trioctylphosphine (TOP) chalcogenide;
injecting the resulting solution into a solution of Cadmium alkyl phosphonate in trioctylphosphine oxide (TOPO);
heating the mixture at temperature from 280° C. to 380° C. under inert atmosphere to obtain sphalerite CdSe nanocrystals with the same habit as the starting Cu₂₋ₓSe nanocrystals.
